(19) United States
(12) Patent Application Publication
(10) Pub. No.: US 2026/0068270 A1
(43) Pub. Date: Mar. 5, 2026

(54) MEMORY DEVICE AND FABRICATING METHOD THEREOF

(71) Applicant: TAIWAN SEMICONDUCTOR MANUFACTURING COMPANY, LTD., Hsinchu (TW)

(72) Inventors: Hung-Li CHIANG, Taipei City (TW); Carlo GILARDI, San Jose, CA (US); Iuliana RADU, Hsinchu County (TW)

(73) Assignee: TAIWAN SEMICONDUCTOR MANUFACTURING COMPANY, LTD., Hsinchu (TW)

(21) Appl. No.: 18/817,629

(22) Filed: Aug. 28, 2024

(51) Int. Cl. H01L 29/417; H10B 12/00

(52) U.S. Cl. CPC H10D 64/258; H10B 12/482; H10B 12/488

(57) ABSTRACT

A device includes a first gain cell. The first gain cell includes a first switch and a second switch. The switch is configured to transmit a first bit line signal to a first storage node. The second switch at least includes a first gate structure coupled to the first storage node and a first source/drain structure corresponding to a first terminal of the second switch. Along a first direction, the first gate structure is disposed above the first switch and the first source/drain structure is disposed above the first gate structure.

### BACKGROUND

A memory device includes multiple gain cells. The gain cells are configured to store data bits and may be formed by Si-only circuits. There is a trade-off between bit cell area and storage node capacitance, since no transistors are placed in the BEOL. An area overhead is typically required to increase storage node capacitance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a circuit diagram of a memory device illustrated in accordance with some embodiments of the present disclosure.

FIG. 1B is a schematic diagram of a cross sectional view of the gain cell shown in FIG. 1A, illustrated in accordance with some embodiments of the present disclosure.

FIG. 2A is a circuit diagram of a memory device corresponding to the memory device shown in FIG. 1A, illustrated in accordance with some embodiments of the present disclosure.

FIG. 2B is a schematic diagram of a cross sectional view of the gain cell shown in FIG. 2A, illustrated in accordance with some embodiments of the present disclosure.

FIG. 3A and FIG. 3B are layout diagrams of a semiconductor device corresponding to the gain cell shown in FIG. 1B, illustrated in accordance with some embodiments of the present disclosure.

FIG. 3C is an alternative layout diagram of the semiconductor device, illustrated in accordance with some embodiments of the present disclosure.

FIG. 4A and FIG. 4B are layout diagrams of a semiconductor device corresponding to the gain cell shown in FIG. 1B, illustrated in accordance with some embodiments of the present disclosure.

FIG. 4C is a circuit diagram of a memory device corresponding to the memory device shown in FIG. 1A, illustrated in accordance with some embodiments of the present disclosure.

FIG. 4D and FIG. 4E are layout diagrams of a semiconductor device corresponding to the memory device shown in FIG. 4C, illustrated in accordance with some embodiments of the present disclosure.

FIG. 5A and FIG. 5B are layout diagrams of a semiconductor device corresponding to the gain cell shown in FIG. 2B, illustrated in accordance with some embodiments of the present disclosure.

FIG. 5C is a circuit diagram of a memory device corresponding to the memory device shown in FIG. 2A, illustrated in accordance with some embodiments of the present disclosure.

FIG. 5D and FIG. 5E are layout diagrams of a semiconductor device corresponding to the memory device shown in FIG. 5C, illustrated in accordance with some embodiments of the present disclosure.

FIG. 6A is a schematic diagram of a cross sectional view of a semiconductor device corresponding to the gain cell shown in FIG. 2A, illustrated in accordance with some embodiments of the present disclosure.

FIG. 6B is a schematic diagram of a cross sectional view of a semiconductor device corresponding to the semiconductor device shown in FIG. 6A, illustrated in accordance with some embodiments of the present disclosure.

FIG. 7A is a timing diagram of operations of the semiconductor device shown in FIG. 1A, illustrated in accordance with some embodiments of the present disclosure.

FIG. 7B is a timing diagram of operations of the semiconductor device shown in FIG. 2A, illustrated in accordance with some embodiments of the present disclosure.

FIG. 7C is a schematic diagram of a memory system, illustrated in accordance with some embodiments of the present disclosure.

FIG. 7D is a flowchart diagram of a method for fabricating the memory devices described above, illustrated in accordance with some embodiments of the present disclosure.

FIG. 8 is a schematic view of a system for designing and manufacturing at least one of the semiconductor devices described above, illustrated in accordance with some embodiments of the present disclosure.

FIG. 9 is a block diagram of an integrated circuit (IC)/semiconductor device manufacturing system, and an IC manufacturing flow associated therewith, illustrated in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

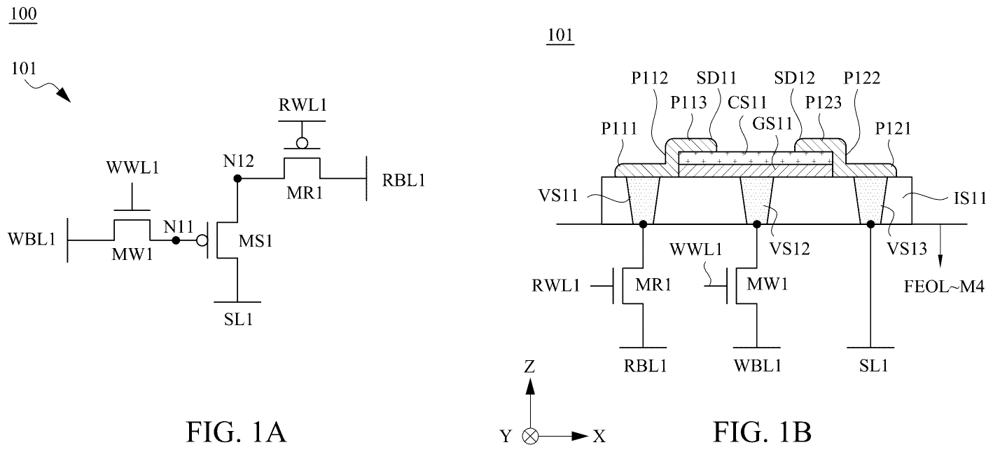

FIG. 1A is a circuit diagram of a memory device 100 illustrated in accordance with some embodiments of the present disclosure. In some embodiments, the memory device 100 includes multiple gain cells, such as a gain cell 101. The gain cells are configured to store data bits.

As illustratively shown in FIG. 1A, the gain cell 101 includes switches MW1, MS1 and MR1. A terminal of the switch MW1 is configured to receive a write bit line signal WBL1, another terminal of the switch MW1 is coupled to a node N11, and a control terminal of the switch MW1 is configured to receive a write word line signal WWL1. A terminal of the switch MS1 is configured to receive a source line signal SL1, another terminal of the switch MS1 is coupled to a node N12, and a control terminal of the switch MS1 is coupled to the node N11. A terminal of the switch MR1 is configured to output a read bit line signal RBL1, another terminal of the switch MR1 is coupled to the node N12, and a control terminal of the switch MR1 is configured to receive a read word line signal RWL1. In some embodiments, the node N11 is referred to as a storage node configured to store a data bit.

In some embodiments, the source line signal SL1 has a ground voltage level or a power supply voltage level higher than the ground voltage level. In various embodiments, each of the switches MW1, MS1 and MR1 is implemented by a P-type transistor or an N-type transistor. For example, in the embodiment shown in FIG. 1A, the switch MW1 is implemented by an N-type transistor, and the switches MS1 and MR1 are implemented by P-type transistors.

FIG. 1B is a schematic diagram of a cross sectional view of the gain cell 101 shown in FIG. 1A, illustrated in accordance with some embodiments of the present disclosure. As illustratively shown in FIG. 1B, the gain cell 101 includes source/drain structures SD11, SD12, a channel structure CS11, a gate structure GS11, via structures VS11-VS13 and isolation structure IS11.

Along a Z direction, the source/drain structures SD11, SD12, the channel structure CS11, the gate structure GS11 are disposed above the via structures VS11-VS13 and the isolation structure IS11, and the via structures VS11-VS13 and the isolation structure IS11 are disposed above the switches MR1 and MW1. The gate structure GS11 is disposed between and coupled to the channel structure CS11 and the via structure VS12. In some embodiments, the via structures VS11-VS13 and the isolation structure IS11 are disposed above front-end-of-line (FEOL) layer to metal-four (M4) layer. The source/drain structures SD11, SD12, the channel structure CS11 and the gate structure GS11 correspond to a back-end-of-line (BEOL) transistor. The BEOL transistor can be fabricated with BEOL-compatible materials, such as amorphous oxides (e.g., IWO, ITO, IGZO), two-dimensional materials (e.g., MoS2, WSe2, WS2), carbon nanotubes. The BEOL transistor is placed directly on top of the FEOL transistors, such as the switches MR1 and MW1.

Along an X direction, the via structures VS11-VS13 are arranged in order, and the channel structure CS11 and the gate structure GS11 are disposed between the source/drain structures SD11 and SD12. The isolation structure IS11 is disposed between the via structures VS11-VS13 to isolate the via structures VS11-VS13 from each other. In some embodiments, the X direction and the Z direction are perpendicular with each other. It is noted that a Y direction points into the paper.

As illustratively shown in FIG. 1B, the source/drain structure SD11 includes portions P111-P113, and the source/drain structure SD12 includes portions P121-P123. The portion P111 elongates along the X direction and is coupled to the via structure VS11. The portion P112 elongates along the Z direction and is adjacent to each of the channel structure CS11 and the gate structure GS11. The portion P113 elongates along the X direction and is coupled to and disposed above the channel structure CS11.

Similarly, the portion P121 elongates along the X direction and is coupled to the via structure VS13. The portion P122 elongates along the Z direction and is adjacent to each of the channel structure CS11 and the gate structure GS11. The portion P123 elongates along the X direction and is coupled to and disposed above the channel structure CS11. The portions P113 and P123 are separated from each other along the X direction.

Referring to FIG. 1A and FIG. 1B, the control terminal of the switch MS1 is implemented by the gate structure GS11, and two terminals of the switch MS1 are implemented by the source/drain structures SD11 and SD12, respectively. The switch MR1 is coupled to the source/drain structure SD11 through the via structure VS11. The switch MW1 is coupled to the gate structure GS11 through the via structure VS12 which corresponds to the node N11. The source/drain structure SD12 is configured to receive the source line signal SL1 through the via structure VS13.

In some approaches, a memory device includes Si-only gain cells. There is a trade-off between bit cell area and storage node capacitance, since no transistors are placed in the BEOL. An area overhead is typically required to increase storage node capacitance. In some other approaches, BEOL transistors are used to reduce the leakage of the storage node by using large band gap materials as write transistors. However, voltage range required requires multiple power rails, leading to area overhead. Moreover, the threshold voltage variability of the write transistor leads to large variability in retention time, with a too short worst-case retention time.

Compared to above approaches, in the embodiments of the present disclosure, the switch MS1 corresponds to a storage transistor and is implemented by a BEOL transistor. Accordingly, a footprint of the switch MS1 is larger, hence increasing the storage node capacitance and gain cell retention time, without increasing the overall bit cell area.

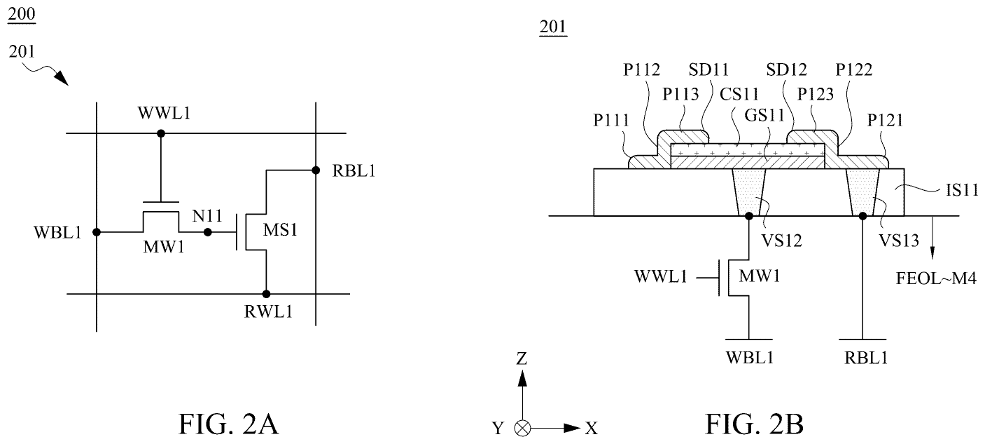

FIG. 2A is a circuit diagram of a memory device 200 corresponding to the memory device 100 shown in FIG. 1A, illustrated in accordance with some embodiments of the present disclosure. The memory device 200 includes multiple gain cells, such as a gain cell 201. Referring to FIG. 2A and FIG. 1A, the memory device 200 is an alternative embodiment of the memory device 100, and the gain cell 201 is an alternative embodiment of the gain cell 101. FIG. 2A follows a similar labeling convention to that of FIG. 1A. For brevity, the discussion will focus more on differences between FIG. 2A and FIG. 1A than on similarities.

Compared to the gain cell 101, the gain cell 201 does not include the switch MR1. The two terminals of the switch MS1 are configured to receive the read bit line signal RBL1 and the read word line signal RWL1, respectively.

FIG. 2B is a schematic diagram of a cross sectional view of the gain cell 201 shown in FIG. 2A, illustrated in accordance with some embodiments of the present disclosure. Referring to FIG. 1B and FIG. 2B, compared to the gain cell 101, the source/drain structure SD11 in the gain cell 201 does not coupled to the via structure VS11. The source/drain structure SD12 is configured to receive the read bit line signal RBL1 through the via structure VS13.

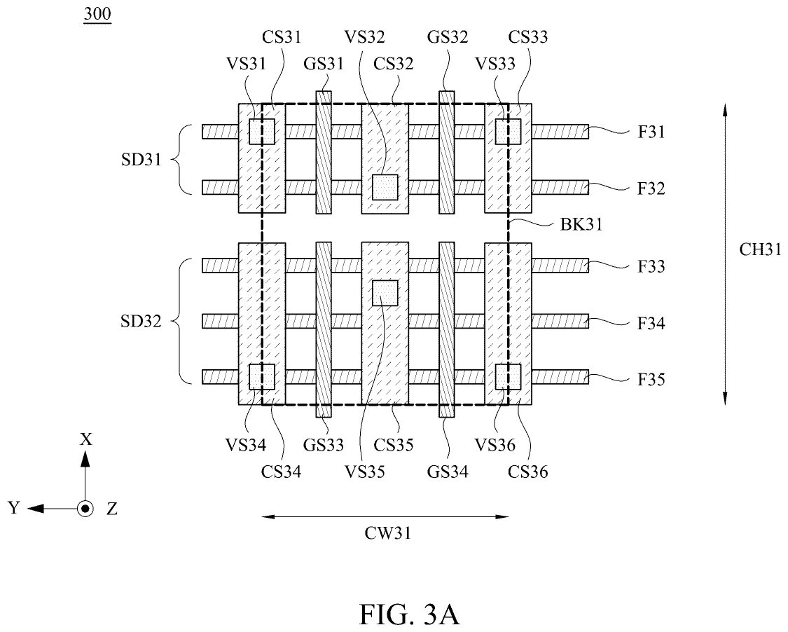

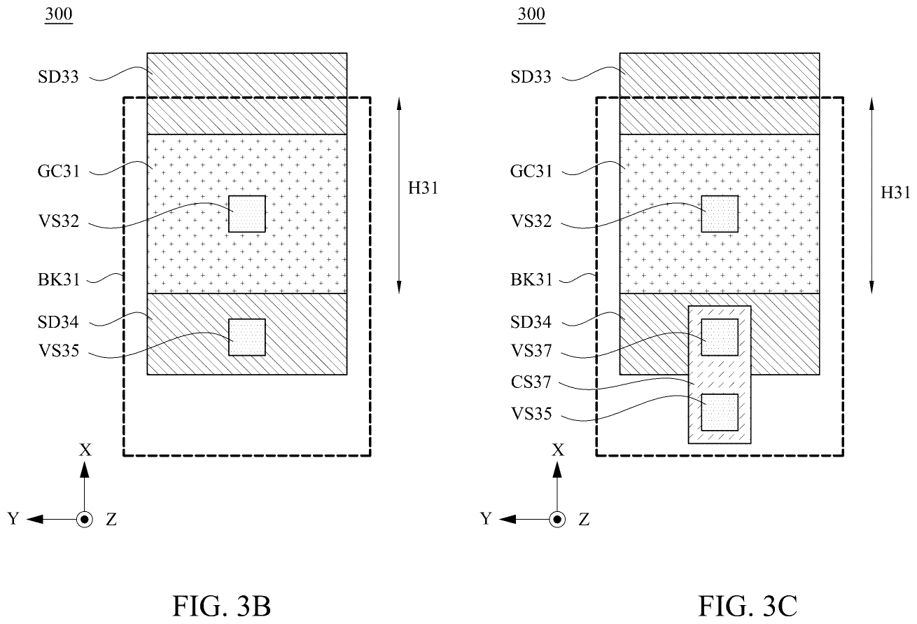

FIG. 3A is a layout diagram of a semiconductor device 300 corresponding to the gain cell 101 shown in FIG. 1B, illustrated in accordance with some embodiments of the present disclosure. In some embodiments, the semiconductor device 300 corresponds to an embedded dynamic random-access memory (eDRAM).

As illustratively shown in FIG. 3A, the semiconductor device 300 includes source/drain structures SD31, SD32, gate structures GS31-GS34, conductive segments CS31-CS36 and via structures VS31-VS36. The source/drain structures SD31 and SD32 are separated from each other along the X direction. Each of the gate structures GS31, GS32 and conductive segments CS31-CS33 crosses over the source/drain structure SD31. Each of the gate structures GS33, GS34 and conductive segments CS34-CS36 crosses over the source/drain structure SD32. The via structures VS31-VS36 are coupled to the conductive segments CS31-CS36, respectively.

Along the Y direction, the conductive segment CS33, the gate structure GS32, the conductive segment CS32, the gate structure GS31 and the conductive segment CS31 are arranged in order, and the conductive segment CS36, the gate structure GS34, the conductive segment CS35, the gate structure GS33 and the conductive segment CS34 are arranged in order. The Z direction points out from the paper in FIG. 3A.

In some embodiments, the source/drain structure SD31 includes two fin structures F31 and F32. The source/drain structure SD32 includes three fin structures F33-F35. Along the X direction, the fin structures F31-F35 are separated from each other. Each of fin structures F31 and F32 is coupled to the gate structures GS31, GS32 and conductive segments CS31-CS33. Each of fin structures F33-F35 is coupled to the gate structures GS33, GS34 and conductive segments CS34-CS36. In other embodiments, the fin structures F31-F35 are replaced by nanosheet structures.

Referring to FIG. 1B and FIG. 3A, the control terminal of the switch MW1 is implemented by the gate structures GS31 and GS32. The via structure VS12 is implemented by the via structure VS32 and corresponds to a source/drain terminal of the switch MW1. Each of the conductive segments CS31 and CS33 is configured to receive the write bit line signal WBL1 and corresponds to another source/drain terminal of the switch MW1. The control terminal of the switch MR1 is implemented by the gate structures GS33 and GS34. The via structure VS11 is implemented by the via structure VS35 and corresponds to a source/drain terminal of the switch MR1. Each of the conductive segments CS34 and CS36 is configured to receive the read bit line signal RBL1 and corresponds to another source/drain terminal of the switch MR1. Accordingly, the switches MW1 and MR1 are implemented by FEOL transistors.

In some embodiments, a size of the cell 101 corresponds to a block BK31 shown in FIG. 3A. The block BK31 has a cell height CH31 along the X direction, and has a cell width CW31 along the Y direction. In some embodiments, the cell height CH31 and the cell width CW31 are approximately equal to 150 nm and 102 nm, respectively. In some embodiments, the cell width CW31 is a distance between a center of the conductive segment CS31 and a center of the conductive segment CS33.

FIG. 3B is a layout diagram of the semiconductor device 300, illustrated in accordance with some embodiments of the present disclosure. As illustratively shown in FIG. 3B, the semiconductor device 300 further includes source/drain structures SD33, SD34 and a gate component GC31. The source/drain structures SD33 and SD34 are separated from each other along the X direction. The gate component GC31 has a height H31 along the X direction. In some embodiments, the height H31 is approximately equal to 100 nm. Each of the source/drain structures SD33 and SD34 is coupled to and partially overlapped with the gate component GC31 along the Z direction. In some embodiments, a gate component includes a channel structure and a gate structure, such as the channel structure CS11 and the gate structure GS11 shown in FIG. 1B.

Referring to FIG. 3A and FIG. 3B, the gate component GC31 is disposed directly above and coupled to the via structure VS32. Along the X direction, the source/drain structures SD33, SD34 and the gate component GC31 are disposed between the conductive segments CS31 and CS33, and are disposed between the conductive segments CS34 and CS36. A part of the via structure VS35 is lower than the source/drain structure SD34.

Referring to FIG. 1B and FIG. 3B, the source/drain structures SD11 and SD12 are implemented by the source/drain structures SD34 and SD33, respectively. The gate component GC31 is implemented by the channel structure CS11 and the gate structure GS11. The source/drain structure SD33 is configured to receive the source line signal SL1.

Referring to FIG. 1A and FIG. 3B, the two source/drain terminals of the switch MS1 are implemented by the source/drain structures SD11 and SD12, respectively. The control terminal of the switch MS1 is implemented by the gate component GC31.

FIG. 3C is an alternative layout diagram of the semiconductor device 300, illustrated in accordance with some embodiments of the present disclosure. Referring to FIG. 3C and FIG. 3B, a structure shown in FIG. 3C is an alternative embodiment of the structure shown in FIG. 3B. FIG. 3C follows a similar labeling convention to that of FIG. 3B. For brevity, the discussion will focus more on differences between FIG. 3C and FIG. 3B than on similarities.

Compared to FIG. 3B, in the embodiment shown in FIG. 3C, the semiconductor device 300 further includes a conductive segment CS37 and a via structure VS37. The conductive segment CS37 is disposed above and partially overlapped with the source/drain structure SD34. The via structure VS37 is configured to couple the conductive segment CS37 to the source/drain structure SD34. The via structure VS35 is coupled to the source/drain structure SD34 through the conductive segment CS37 and the via structure VS37.

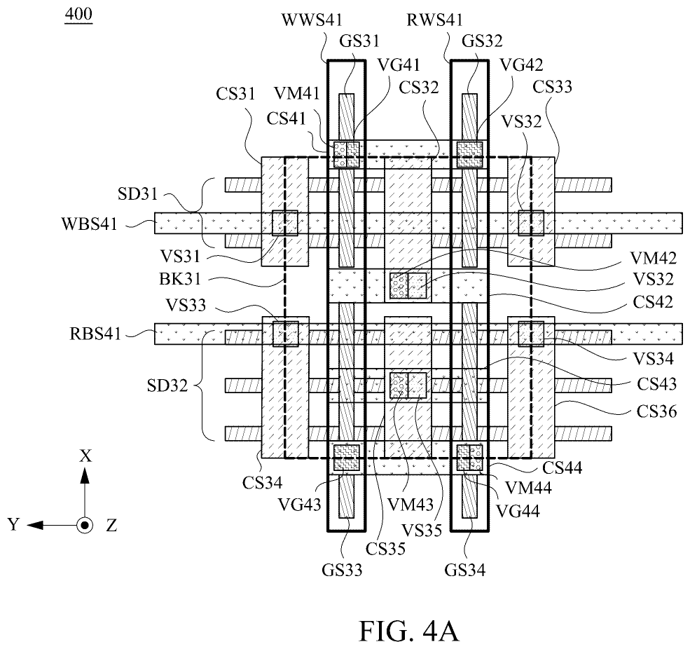

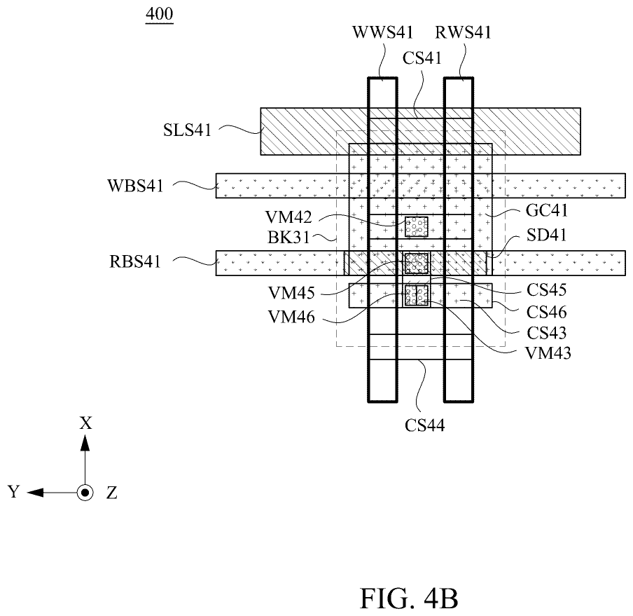

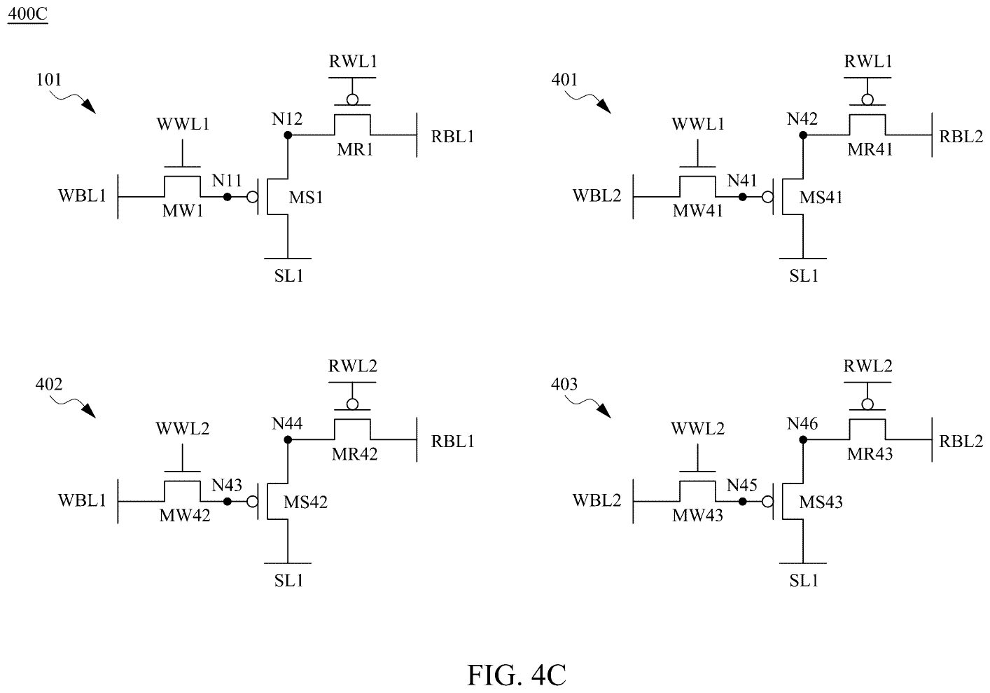

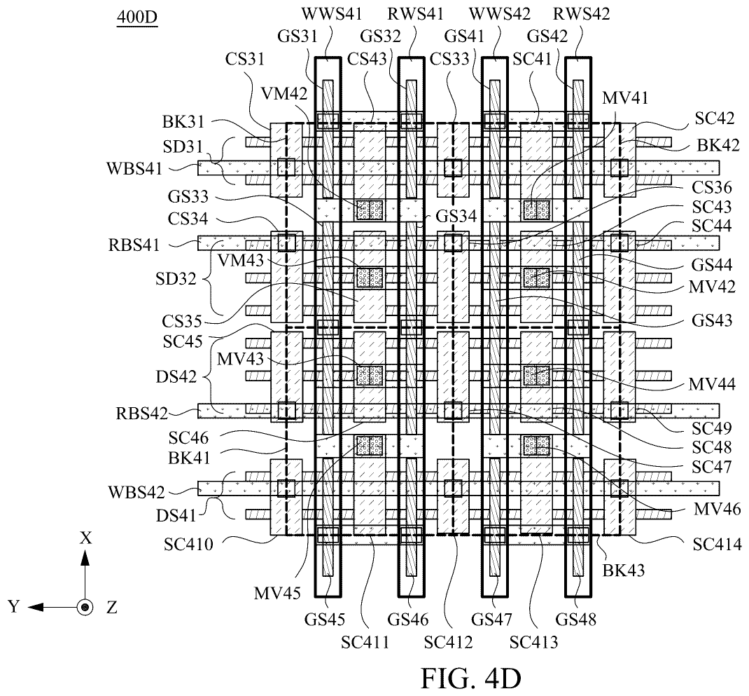

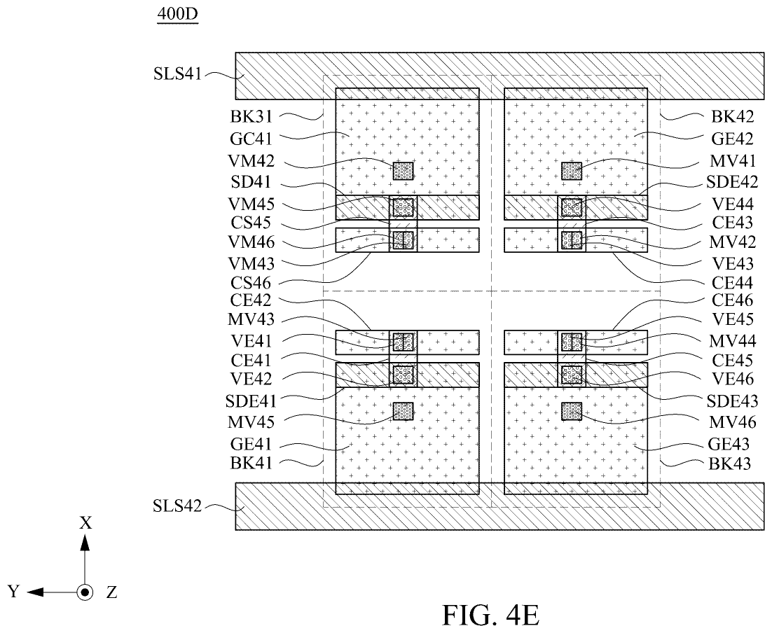

FIG. 4A is a layout diagram of a semiconductor device 400 corresponding to the gain cell 101 shown in FIG. 1B, illustrated in accordance with some embodiments of the present disclosure. Referring to FIG. 4A and FIG. 3A, the semiconductor device 400 is an alternative embodiment of the semiconductor device 300. FIG. 4A follows a similar labeling convention to that of FIG. 3A. For brevity, the discussion will focus more on differences between FIG. 4A and FIG. 3A than on similarities.

Compared to the semiconductor device 300, the semiconductor device 400 further includes word line structures WWS41, RWS41, bit line structures WBS41, RBS41, conductive segments CS41-CS44 and via structures VM41-VM44, VG41-VG44.

As illustratively shown in FIG. 4A, the conductive segments CS41-CS44 are arranged along the X direction in order. Along the X direction, the bit line structure WBS41 is disposed between the conductive segments CS41 and CS42, the bit line structure RBS41 is disposed between the conductive segments CS43 and CS44, and the conductive segment CS42 is disposed between the bit line structures WBS41 and RBS41. The bit line structure WBS41 crosses over the conductive segments CS31-CS33, and the bit line structure RBS41 crosses over the conductive segments CS34-CS36. The bit line structure RBS41 and the conductive segment CS43 are overlapped with the fin structures F33 and F34, respectively.

Along the Y direction, the word line structure WWS41 is disposed between the conductive segments CS31 and CS32 and between the conductive segments CS34 and CS35, and the word line structure RWS41 is disposed between the conductive segments CS33 and CS32 and between the conductive segments CS36 and CS35. Each of the word line structures WWS41 and RWS41 crosses over the source/drain structures SD31 and SD32. The word line structure WWS41 is overlapped with each of the gate structure GS31 and GS33. The word line structure RWS41 is overlapped with each of the gate structure GS32 and GS34.

In some embodiments, the gate structure GS31 is coupled to the conductive segment CS41 through the via structure VG41. The gate structure GS32 is coupled to the conductive segment CS41 through the via structure VG42. The conductive segment CS41 is coupled to the word line structure WWS41 through the via structure VM41.

Similarly, the gate structure GS33 is coupled to the conductive segment CS44 through the via structure VG43. The gate structure GS34 is coupled to the conductive segment CS44 through the via structure VG44. The conductive segment CS44 is coupled to the word line structure RWS41 through the via structure VM44.

In some embodiments, the conductive segment CS32 is coupled to the conductive segment CS42 through the via structure VS32. The conductive segment CS35 is coupled to the conductive segment CS43 through the via structure VS35. The via structures VM42 and VM43 are disposed above and coupled to the conductive segments CS42 and CS43, respectively.

In some embodiments, the conductive segment CS31 is coupled to the bit line structure WBS41 through the via structure VS31. The conductive segment CS33 is coupled to the bit line structure WBS41 through the via structure VS33. The conductive segment CS34 is coupled to the bit line structure RBS41 through the via structure VS34. The conductive segment CS36 is coupled to the bit line structure RBS41 through the via structure VS36.

Referring to FIG. 1B and FIG. 4A, the word line structure WWS41 is configured to transmit the write word line signal WWL1 to the gate structures GS31 and GS32, which correspond to the control terminal of the switch MW1. The word line structure RWS41 is configured to transmit the read word line signal RWL1 to the gate structures GS33 and GS34, which correspond to the control terminal of the switch MR1. The bit line structure WBS41 is configured to transmit the write bit line signal WBL1 to the conductive segments CS31 and CS33, which correspond to the source/drain terminal of the switch MW1. The conductive segment CS32 corresponds to the other source/drain terminal of the switch MW1. The bit line structure RBS41 is configured to transmit the read bit line signal RBL1 to the conductive segments CS34 and CS36, which correspond to the source/drain terminal of the switch MR1. The conductive segment CS35 corresponds to the other source/drain terminal of the switch MR1.

FIG. 4B is a layout diagram of the semiconductor device 400, illustrated in accordance with some embodiments of the present disclosure. As illustratively shown in FIG. 4B, the semiconductor device 400 further includes a source/drain structure SD41, a source line structure SLS41, a gate component GC41, conductive segments CS45, CS46. The source/drain structure SD41 and the source line structure SLS41 are separated from each other along the X direction. Each of the source/drain structure SD41 and the source line structure SLS41 is coupled to and partially overlapped with the gate component GC41.

Along the X direction, the conductive segment CS46 is separated from the source line structure SLS41. The conductive segment CS45 crosses over each of the source/drain structure SD41 and the conductive segment CS46, and is coupled to the source/drain structure SD41 and the conductive segment CS46 through the via structures VM45 and VM46, respectively.

Along the Z direction, the source line structure SLS41 is overlapped with and disposed above the conductive segment CS41, the gate component GC41 is overlapped with and disposed above the conductive segment CS42, the bit line structures WBS41, RBL41 and the word line structures WWS41, RWL41. The conductive segment CS46 is overlapped with and disposed above the conductive segment CS43.

Referring to FIG. 4A and FIG. 4B, the gate component GC41 is coupled to the via structure VM42. The conductive segment CS46 is coupled to the via structure VM43. In some embodiment, the bit line structures WBS41, RBL41 and the conductive segments CS41-CS44 are located in a metal one (M1) layer. The word line structures WWS41, RWL41 are located in a metal two (M2) layer, which is above the M1 layer. The gate component GC41 and the conductive segment CS46 are located in a metal three (M3) layer, which is above the M2 layer. The source line structure SLS41 and the source/drain structure are located in a metal four (M4) layer, which is above the M3 layer. The conductive segment CS46 is located in a metal five (M5) layer, which is above the M4 layer.

Referring to FIG. 1B and FIG. 4B, the source/drain structures SD11 and SD12 are implemented by the source/drain structure SD41, the source line structure SLS41, respectively. The channel structure CS11 and the gate structure GS11 are implemented by the gate component GC41. The source line structure SLS41 is configured to receive the source line signal SL1.

Referring to FIG. 1A and FIG. 4B, the two source/drain terminal of the switch MS1 are implemented by the source line structure SLS41 and the source/drain structure SD41, respectively. The control terminal of the switch MS1 is implemented by the gate component GC41.

FIG. 4C is a circuit diagram of a memory device 400C corresponding to the memory device 100 shown in FIG. 1A, illustrated in accordance with some embodiments of the present disclosure. Referring to FIG. 4C and FIG. 1A, a memory device 400C is an alternative embodiment of the memory device 100. FIG. 4C follows a similar labeling convention to that of FIG. 1A. For brevity, the discussion will focus more on differences between FIG. 4C and FIG. 1A than on similarities.

Compared to the memory device 100, the memory device 400C further includes gain cells 401-403. The gain cell 401 includes switches MW41, MS41 and MR41. The gain cell 402 includes switches MW42, MS42 and MR42. The gain cell 403 includes switches MW43, MS43 and MR43.

As illustratively shown in FIG. 4C, a terminal of the switch MW41 is configured to receive a write bit line signal WBL2, another terminal of the switch MW41 is coupled to a node N41, and a control terminal of the switch MW41 is configured to receive the write word line signal WWL1. A terminal of the switch MS41 is configured to receive the source line signal SL1, another terminal of the switch MS41 is coupled to a node N42, and a control terminal of the switch MS41 is coupled to the node N41. A terminal of the switch MR41 is configured to output a read bit line signal RBL2, another terminal of the switch MR41 is coupled to the node N42, and a control terminal of the switch MR41 is configured to receive the read word line signal RWL1.

Similarly, a terminal of the switch MW42 is configured to receive the write bit line signal WBL1, another terminal of the switch MW42 is coupled to a node N43, and a control terminal of the switch MW42 is configured to receive a write word line signal WWL2. A terminal of the switch MS42 is configured to receive the source line signal SL1, another terminal of the switch MS42 is coupled to a node N44, and a control terminal of the switch MS42 is coupled to the node N42. A terminal of the switch MR42 is configured to output the read bit line signal RBL2, another terminal of the switch MR42 is coupled to the node N44, and a control terminal of the switch MR42 is configured to receive a read word line signal RWL2.

Similarly, a terminal of the switch MW43 is configured to receive the write bit line signal WBL2, another terminal of the switch MW43 is coupled to a node N45, and a control terminal of the switch MW43 is configured to receive the write word line signal WWL2. A terminal of the switch MS43 is configured to receive the source line signal SL1, another terminal of the switch MS43 is coupled to a node N46, and a control terminal of the switch MS43 is coupled to the node N45. A terminal of the switch MR43 is configured to output the read bit line signal RBL2, another terminal of the switch MR43 is coupled to the node N46, and a control terminal of the switch MR43 is configured to receive the read word line signal RWL2. In some embodiments, the nodes N41, N43 and N45 are referred to as storage nodes configured to store data bits.

FIG. 4D is a layout diagram of a semiconductor device 400D corresponding to the memory device 400C shown in FIG. 4C, illustrated in accordance with some embodiments of the present disclosure. Referring to FIG. 4A and FIG. 4D, the semiconductor device 400D is an alternative embodiment of the semiconductor device 400. FIG. 4D follows a similar labeling convention to that of FIG. 4A. For brevity, the discussion will focus more on differences between FIG. 4D and FIG. 4A than on similarities, and some labels are not shown in FIG. 4D, such as the labels of the conductive segments CS41-CS44 and the via structures VG41-VG44.

Compared to the semiconductor device 400, the semiconductor device 400D further includes source/drain structures DS41, DS42, gate structures GS41-GS48, conductive segments SC41-SC414, bit line structures WBS42, RBS42 and word line structures WWS42, RWS42.

As illustratively shown in FIG. 4D, the source/drain structures DS41, DS42, SD32 and SD31 are separated from each other and arranged in order along the X direction. The conductive segments SC41-SC414 and CS31-CS36 are separated from each other. The source/drain structure DS41 includes two fin structures, and the source/drain structure DS42 includes three fin structures.

The gate structure GS32, the conductive segment CS33, the gate structure GS41, the conductive segment SC41, the gate structure GS42 and the conductive segment SC42 are arranged in order along the Y direction and cross over the source/drain structure SD31. Similarly, the gate structure GS34, the conductive segment CS36, the gate structure GS43, the conductive segment SC43, the gate structure GS44 and the conductive segment SC44 are arranged in order along the Y direction and cross over the source/drain structure SD32.

The conductive segment SC45, the gate structure GS33, the conductive segment CS46, the gate structure GS34, the conductive segment SC47, the gate structure GS43, the conductive segment SC48, the gate structure GS44 and the conductive segment SC49 are arranged in order along the Y direction and cross over the source/drain structure DS42. It is noted that the gate structure GS33, GS34, GS43 and GS44 crosses over each of the source/drain structures SD32 and DS42.

Similarly, the conductive segment SC410, the gate structure GS45, the conductive segment CS411, the gate structure GS46, the conductive segment SC412, the gate structure GS47, the conductive segment SC413, the gate structure GS48 and the conductive segment SC414 are arranged in order along the Y direction and cross over the source/drain structure DS41.

As illustratively shown in FIG. 4D, the bit line structures WBS41, RBS41, RBS42 and WBS42 are arranged in order along the Y direction. The word line structures WWS41, RWS41, WWS42 and WWS42 are arranged in order along the X direction.

The bit line structure WBS41 crosses over and coupled to each of the conductive segments CS31, CS33 and SC42 through corresponding via structures. The bit line structure RBS41 crosses over and coupled to each of the conductive segments CS34, CS36 and SC44 through corresponding via structures. The bit line structure WBS41 crosses over and coupled to each of the conductive segments CS31, CS33 and SC42 through corresponding via structures. The bit line structure RBS42 crosses over and coupled to each of the conductive segments SC45, SC47 and SC49 through corresponding via structures. The bit line structure WBS42 crosses over and coupled to each of the conductive segments SC410, SC412 and SC414 through corresponding via structures.

Each of the word line structures WWS41, WWS42, RWS41 and RWS42 crosses over the source/drain structures SD31, SD32, DS41 and DS42. The word line structure WWS41 is coupled to each of the gate structures GS31, GS32, GS45 and GS46 through corresponding via structures and conductive segments. The word line structure WWS42 is coupled to each of the gate structures GS41, GS42, GS47 and GS48 through corresponding via structures and conductive segments. The word line structure RWS41 is coupled to each of the gate structures GS33 and GS34 through corresponding via structures and conductive segments. The word line structure RWS42 is coupled to each of the gate structures GS43 and GS44 through corresponding via structures and conductive segments.

As illustratively shown in FIG. 4D, the semiconductor device 400D further includes via structures MV41-MV46. The via structures MV41-MV46 are respectively disposed above and coupled to the conductive segments SC41, SC43, SC46, SC48, SC411 and SC413, through corresponding via structures and conductive segments.

Referring to FIG. 4C and FIG. 4D, the memory device 400C is implemented by the semiconductor device 400D in some embodiments. In such embodiments, the gate structures GS41 and GS42 correspond to the control terminal of the switch MW42. The gate structures GS33 and GS34 correspond to the control terminals of the switches MR1 and MR41. The gate structures GS43 and GS44 correspond to the control terminals of the switches MR42 and MR43. The gate structures GS45 and GS46 correspond to the control terminal of the switch MW41. The gate structures GS47 and GS48 correspond to the control terminal of the switch MW43. The conductive segments SC41, SC43, SC46, SC48, SC411 and SC413 correspond to the nodes N43, N44, N42, N46, N41 and N45, respectively.

Furthermore, the word line structure WWS41 is configured to transmit the write word line signal WWL1 to each of the gate structures GS31, GS32, GS45 and GS46. The word line structure WWS42 is configured to transmit the write word line signal WWL2 to each of the gate structures GS41, GS42, GS47 and GS48. The word line structure RWS41 is configured to transmit the read word line signal RWL1 to each of the gate structures GS33 and GS34. The word line structure RWS42 is configured to transmit the read word line signal RWL2 to each of the gate structures GS43 and GS44.

Moreover, the bit line structure WBS41 is configured to transmit the write bit line signal WBL1 to each of the conductive segments CS31, CS33 and SC42 through corresponding via structures. The bit line structure WBS42 is configured to transmit the write bit line signal WBL2 to each of the conductive segments SC410, SC412 and SC414 through corresponding via structures. The bit line structure RBS41 is configured to transmit the read bit line signal RBL1 to each of the conductive segments CS34, CS36 and SC44 through corresponding via structures. The bit line structure RBS42 is configured to transmit the read bit line signal RBL2 to each of the conductive segments SC45, SC48 and SC49 through corresponding via structures.

Referring to FIG. 4C and FIG. 4D, the semiconductor device 400D includes blocks BK31 and BK41-BK43. The blocks BK31 and BK41-BK43 correspond to the gain cells 101 and 401-403, respectively. Each of the blocks BK31 and BK41-BK43 has the cell height CH31 along the X direction, and has the cell width CW31 along the Y direction.

FIG. 4E is a layout diagram of the semiconductor device 400D, illustrated in accordance with some embodiments of the present disclosure. Referring to FIG. 4B and FIG. 4E, the semiconductor device 400D is an alternative embodiment of the semiconductor device 400. FIG. 4E follows a similar labeling convention to that of FIG. 4B. For brevity, the discussion will focus more on differences between FIG. 4E and FIG. 4B than on similarities.

Compared to the semiconductor device 400, the semiconductor device 400D further includes a source line structure SLS42, source/drain structures SDE41-SDE43, gate components GE41-GE43, conductive segments CE41-CE46 and via structures VE41-VE46. The gate component GE41 and the conductive segments CE41, CE42 are located in the block BK41. The gate component GE42 and the conductive segments CE43, CE44 are located in the block BK42. The gate component GE43 and the conductive segments CE45, CE46 are located in the block BK43.

As illustratively shown in FIG. 4E, the source line structure SLS42, the source/drain structure SDE41, the conductive segments CE42, CS46, the source/drain structure SD41 and the source line structure SLS41 are arranged in order along the X direction, and are separated from each other. The source line structure SLS42, the source/drain structure SDE43 the conductive segments CE46, CE44, the source/drain structure SDE42 and the source line structure SLS41 are arranged in order along the X direction, and are separated from each other.

In some embodiments, each of the source line structure SLS42 and the source/drain structure SDE41 is overlapped with and coupled to the gate component GE41. Each of the source line structure SLS42 and the source/drain structure SDE43 is overlapped with and coupled to the gate component GE43. Each of the source line structure SLS41 and the source/drain structure SDE42 is overlapped with and coupled to the gate component GE42.

The via structures VE41, VE43, VE45, VE42, VE44 and VE46 are disposed above and coupled to the conductive segments CE42, CE44, CE46, the source/drain structures SDE41, SDE42 and SDE43, respectively. The conductive segment CE41 is disposed above and coupled to each of the via structures VE41 and VE42. The conductive segment CE43 is disposed above and coupled to each of the via structures VE43 and VE44. The conductive segment CE45 is disposed above and coupled to each of the via structures VE45 and VE46.

Referring to FIG. 4D and FIG. 4E, the conductive segments CE42, CE44, CE46, the gate components GE41, GE42 and GE43 are disposed above and coupled to the via structures MV43, MV42, MV44, MV45, MV41 and MV46, respectively.

In the layout view shown in FIG. 4D and FIG. 4E, the gate component GE41 is overlapped with each of the bit line structures RBS42, WBS42 and the word line structures WWS41, RWS41. The gate component GE42 is overlapped with each of the bit line structures RBS41, WBS41 and the word line structures WWS42, RWS42. The gate component GE43 is overlapped with each of the bit line structures RBS42, WBS42 and the word line structures WWS42, RWS42.

Referring to FIG. 4C and FIG. 4E, the memory device 400C is implemented by the semiconductor device 400D in some embodiments. In such embodiments, the control terminals of the switches MS1 and MS41-MS43 are implemented by the gate components GC41 and GE41-GE43, respectively. Each of the source line structures SLS41 and SLS42 is configured to transmit the source line signal SL1 to the switches MS1 and MS41-MS43. The source/drain structures SD41, SDE41, SDE42 and SDE43 correspond to the nodes N11, N42, N44 and N46, respectively. The source line structure SLS41 is configured to operate as source/drain terminals of the switches MS1 and MS42. The source line structure SLS42 is configured to operate as source/drain terminals of the switches MS41 and MS43.

Alternatively stated, the switch MS1 is coupled to the switch MR1 through the conductive segments CS45 and CS46. The switch MS41 is coupled to the switch MR41 through the conductive segments CE41 and CE42. The switch MS42 is coupled to the switch MR42 through the conductive segments CE43 and CE44. The switch MS43 is coupled to the switch MR43 through the conductive segments CE45 and CE46.

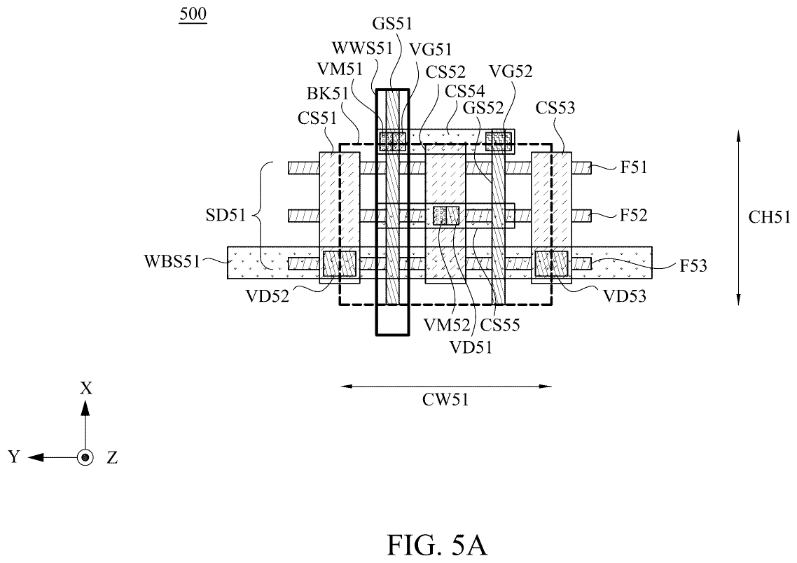

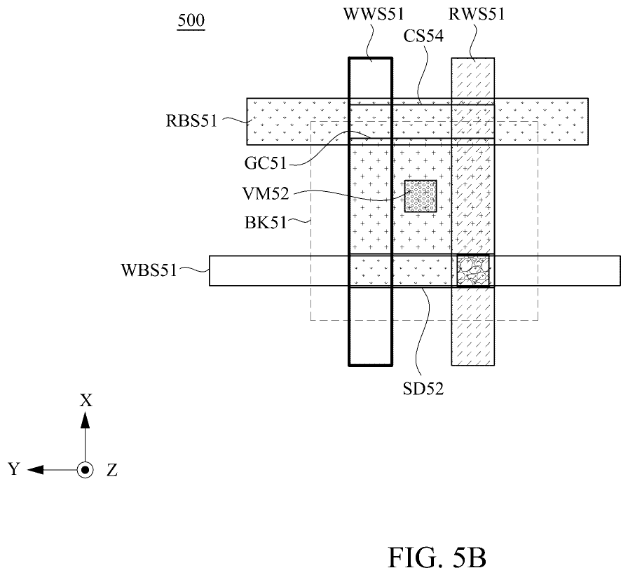

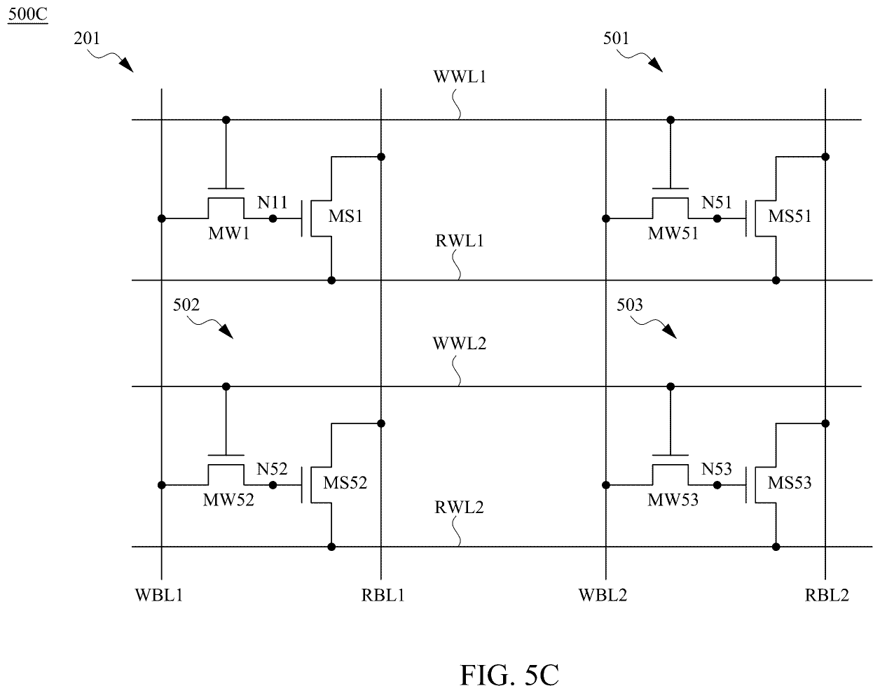

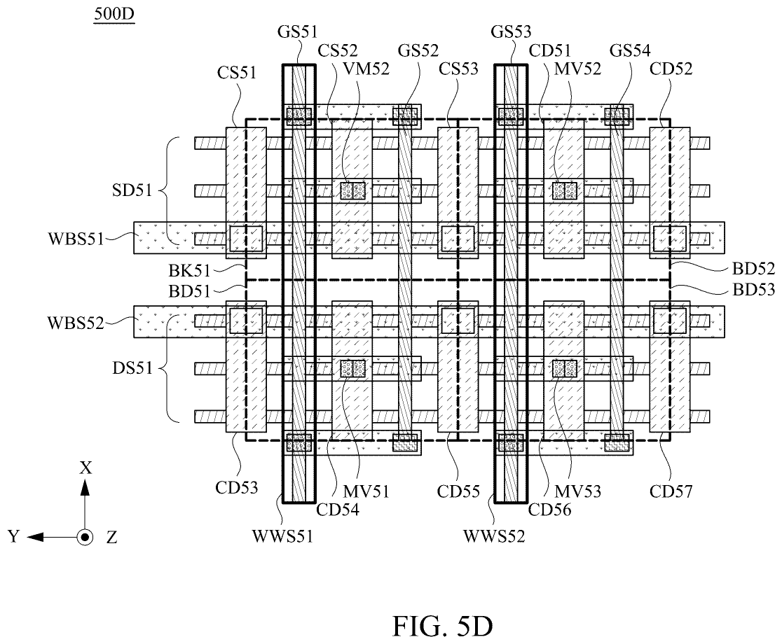

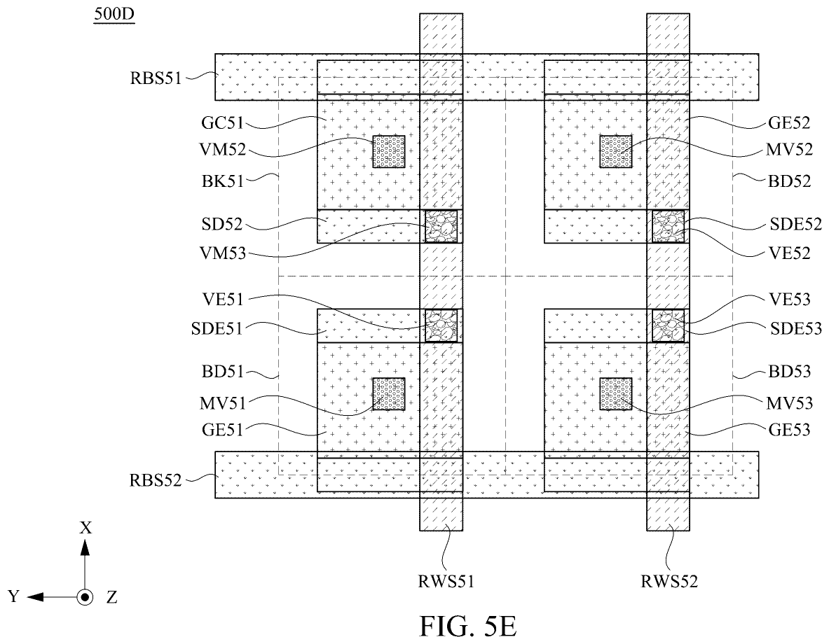

FIG. 5A is a layout diagram of a semiconductor device 500 corresponding to the gain cell 201 shown in FIG. 2B, illustrated in accordance with some embodiments of the present disclosure.

As illustratively shown in FIG. 5A, the semiconductor device 500 includes a source/drain structure SD51, gate structures GS51-GS52, conductive segments CS51-CS55 and via structures VM51, VM52, VG51, VG52, VD51-VD53, a word line structure WWS51 and a bit line structure WBS51. The conductive segment CS51, the gate structure GS51, the conductive segment CS52, the gate structure GS52 and the conductive segment CS53 are arranged along the Y direction in order, and cross over and coupled to the source/drain structure SD51. The source/drain structure SD51 includes fin structures F51-F53 separated from each other.

The conductive segment CS54 crosses over each of the gate structures VG51 and VG52, and is coupled to the gate structures VG51 and VG52 through the via structures VG51 and VG52, respectively. The conductive segment CS54 crosses over the conductive segment CS52 and is coupled to the conductive segment CS52 through the via structure VD51. The word line structure WWS51 crosses over each of the conductive segment CS54 and the source/drain structure SD51, and is coupled to the conductive segment CS54 through the via structure VM51. The bit line structure WBS51 crosses over each of the conductive segments CS51 and CS53, and is coupled to the conductive segments CS51 and CS53 through the via structures VD52 and VD53, respectively. The conductive segment CS55 crosses over and coupled to the conductive segment CS52 through the via structure VD51. The via structure VM52 is disposed above and coupled to the conductive segment CS55.

Referring to FIG. 2B and FIG. 5A, the gain cell 201 is implemented by the semiconductor device 500 in some embodiments. In such embodiments, the control terminal of the switch MW1 is implemented by the gate structures GS51 and GS52. The word line structure WWS51 is configured to transmit the write word line signal WWL1 to the conductive segment CS54, which correspond to a source/drain terminal of the switch MW1. The bit line structure WBS51 is configured to transmit the write bit line signal WBL1 to the conductive segments CS51 and CS53, which correspond to another source/drain terminal of the switch MW1. The via structure VS12 is implemented by the via structure VM52.

In some embodiments, a size of the cell 201 corresponds to the block BK51 shown in FIG. 5A. The block BK51 has a cell height CH51 along the X direction, and has a cell width CW51 along the Y direction. In some embodiments, the cell height CH51 is within a range of 90 nm to 120 nm. The cell width CW51 is approximately equal to 102 nm. In some embodiments, the cell width CW51 is a distance between a center of the conductive segment CS51 and a center of the conductive segment CS53.

FIG. 5B is a layout diagram of the semiconductor device 500, illustrated in accordance with some embodiments of the present disclosure. As illustratively shown in FIG. 5B, the semiconductor device 500 further includes bit line structures RBS51, a word line structure RWS51, a gate component GC51 and a source/drain structure SD52.

The bit line structures RBS51 and the source/drain structure SD52 are separated from each other along the X direction, and are disposed above, overlapped with and coupled to the gate component GC51. The word line structure RWS51 crosses over each of the bit line structures RBS51 and the source/drain structure SD52, and is coupled to the source/drain structure SD52 through the via structure VM53. The gate component GC51 is disposed above and coupled to the via structure VM52.

Referring to FIG. 2B and FIG. 5B, the gain cell 201 is implemented by the semiconductor device 500 in some embodiments. In such embodiments, the gate component GC51 corresponds to the control terminal of the switch MS1 and is implemented by the gate structure GS11 and the channel structure CS11. The bit line structure RBS51 is implemented by the source/drain structure SD12 and configured to receive the read bit line signal RBL1. The source/drain structure SD52 is implemented by the source/drain structure SD11. The word line structure RWS51 is configured to transmit the read word line signal through the via structure VM53 to the source/drain structure SD52.

FIG. 5C is a circuit diagram of a memory device 500C corresponding to the memory device 200 shown in FIG. 2A, illustrated in accordance with some embodiments of the present disclosure. Referring to FIG. 5C and FIG. 2A, a memory device 500C is an alternative embodiment of the memory device 200. FIG. 5C follows a similar labeling convention to that of FIG. 2A. For brevity, the discussion will focus more on differences between FIG. 5C and FIG. 2A than on similarities.

Compared to the memory device 200, the memory device 500C further includes gain cells 501-503. The gain cell 501 includes switches MW51 and MS51. The gain cell 502 includes switches MW52 and MS52. The gain cell 503 includes switches MW53 and MS53.

As illustratively shown in FIG. 5C, a terminal of the switch MW51 is configured to receive the write bit line signal WBL2, another terminal of the switch MW51 is coupled to a node N51, and a control terminal of the switch MW51 is configured to receive the write word line signal WWL1. A terminal of the switch MS51 is configured to receive the read word line RWL1, another terminal of the switch MS51 is configured to receive the read bit line RBL2, and a control terminal of the switch MS51 is coupled to the node N51.

Similarly, a terminal of the switch MW52 is configured to receive the write bit line signal WBL1, another terminal of the switch MW52 is coupled to a node N52, and a control terminal of the switch MW52 is configured to receive the write word line signal WWL2. A terminal of the switch MS52 is configured to receive the read word line RWL2, another terminal of the switch MS52 is configured to receive the read bit line RBL1, and a control terminal of the switch MS52 is coupled to the node N52.

Similarly, a terminal of the switch MW53 is configured to receive the write bit line signal WBL2, another terminal of the switch MW53 is coupled to a node N53, and a control terminal of the switch MW53 is configured to receive the write word line signal WWL2. A terminal of the switch MS53 is configured to receive the read word line RWL2, another terminal of the switch MS53 is configured to receive the read bit line RBL2, and a control terminal of the switch MS53 is coupled to the node N53. In some embodiments, the nodes N51-N53 are referred to as storage nodes configured to store data bits.

FIG. 5D is a layout diagram of a semiconductor device 500D corresponding to the memory device 500C shown in FIG. 5C, illustrated in accordance with some embodiments of the present disclosure. Referring to FIG. 5A and FIG. 5D, the semiconductor device 500D is an alternative embodiment of the semiconductor device 500. FIG. 5D follows a similar labeling convention to that of FIG. 5A. For brevity, the discussion will focus more on differences between FIG. 5D and FIG. 5A than on similarities, and some labels are not shown in FIG. 5D, such as the labels of the conductive segments CS54-CS55 and the via structures VG51-VG52.

Compared to the semiconductor device 500, the semiconductor device 500D further includes a source/drain structure DS51, gate structures GS53-GS54, conductive segments CD51-CD57, via structures MV51-MV53, a bit line structure WBS52 and a word line structure WWS52. The source/drain structure DS51 is separated from the source/drain structure SD51, and includes three fin structures separated from each other.

Along the Y direction, the conductive segment CS51, the gate structure GS51, the conductive segment CS52, the gate structure GS52, the conductive segment CS53, the gate structure GS53, the conductive segment CD51, the gate structure GS54 and the conductive segment CD52 are arranged in order, and the conductive segment CD53, the gate structure GS51, the conductive segment CD54, the gate structure GS52, the conductive segment CD55, the gate structure GS53, the conductive segment CD56, the gate structure GS54 and the conductive segment CD57 are arranged in order.

The conductive segments CS51-CS53 and CD51-CD52 cross over and are coupled to the source/drain structure SD51. The conductive segments CD53-CD57 cross over and are coupled to the source/drain structure DS51. The gate structures GS51-GS54 cross over and are coupled to each of the source/drain structures SD51 and DS51.

The bit line structure WBS51 crosses over and coupled to each of the conductive segments CS51, CS53 and CD52 through corresponding via structures. The bit line structure WBS52 crosses over and coupled to each of the conductive segments CD53, CD55 and CD57 through corresponding via structures. The word line structure WWS51 crosses over each of the source/drain structures SD51 and DS51, and coupled to each of the gate structures GS51 and GS52 through corresponding via structures and conductive segments. The word line structure WWS52 crosses over each of the source/drain structures SD51 and DS51, and coupled to each of the gate structures GS53 and GS54 through corresponding via structures and conductive segments. The via structures MV51-MV53 are respectively disposed above and coupled to the conductive segments CD54, CD51 and CD56, through corresponding via structures and conductive segments.

Referring to FIG. 5C and FIG. 5D, the memory device 500C is implemented by the semiconductor device 500D in some embodiments. In such embodiments, the gate structures GS51 and GS52 correspond to each of the control terminals of the switches MW1 and MW51. The gate structures GS53 and GS54 correspond to each of the control terminals of the switches MW52 and MW53. The word line structure WWS51 is configured to transmit the write word line signal WWL1 to the switches MW1 and MW51. The word line structure WWS52 is configured to transmit the write word line signal WWL2 to the switches MW52 and MW53.

Furthermore, the conductive segments CS52, CD51, CD54 and CD56 correspond to the nodes N11, N52, N51 and N53, respectively. The bit line structure WBS51 is configured to transmit the write bit line signal WBL1 through the conductive segments CS51, CS53 and CD52 to the switches MW1 and MW52. The bit line structure WBS52 is configured to transmit the write bit line signal WBL2 through the conductive segments CD53, CD55 and CD57 to the switches MW51 and MW53.

Referring to FIG. 5C and FIG. 5D, the semiconductor device 400D includes blocks BK51 and BD51-BD53. The blocks BK51 and BD51-BD53 correspond to the gain cells 201 and 501-503, respectively. Each of the blocks BK51 and BD51-BD53 has the cell height CH51 along the X direction, and has the cell width CW51 along the Y direction.

FIG. 5E is a layout diagram of the semiconductor device 500D, illustrated in accordance with some embodiments of the present disclosure. Referring to FIG. 5B and FIG. 5E, the semiconductor device 500D is an alternative embodiment of the semiconductor device 500. FIG. 5E follows a similar labeling convention to that of FIG. 5B. For brevity, the discussion will focus more on differences between FIG. 5E and FIG. 5B than on similarities.

Compared to the semiconductor device 500, the semiconductor device 500D further includes a bit line structure RBS52, a word line structure RWS52, source/drain structures SDE51-SDE53, gate components GE51-GE53 and via structures VE51-VE53. The gate component GE51 and the source/drain structure SDE51 are located in the block BD51. The gate component GE52 and the source/drain structure SDE52 are located in the block BD52. The gate component GE53 and the source/drain structure SDE53 are located in the block BD53.

As illustratively shown in FIG. 5E, the bit line structure RBS51, the source/drain structures SD52, SDE51, and the bit line structure RBS52 arranged in order along the X direction, and are separated from each other. The bit line structure RBS51, the source/drain structures SDE52, SDE53, and the bit line structure RBS52 arranged in order along the X direction, and are separated from each other.

The bit line structure RBS51 is partially overlapped with and coupled to each of the gate components GC51 and GE52. The bit line structure RBS52 is partially overlapped with and coupled to each of the gate components GE51 and GE53. The source/drain structures SD52 and SDE51-SDE53 are overlapped with and coupled to the gate components GC51 and GE51-GE53, respectively.

The word line structure RWS51 crosses over each of the bit line structures RBS51 and RBS52, and is coupled to the source/drain structures SD52 and SDE51 through the via structures VM53 and VE51, respectively. The word line structure RWS52 crosses over each of the bit line structures RBS51 and RBS52, and is coupled to the source/drain structures SDE52 and SDE53 through the via structures VE52 and VE53, respectively. Referring to FIG. 5D and FIG. 5E, the gate components GC51 and GE51-GE53 are disposed above and coupled to the via structures VM52 and MV51-MV53, respectively.

Referring to FIG. 5C and FIG. 5E, the control terminals of the switches MS1 and MS51-MS53 are implemented by the gate components GC51 and GE51-GE53, respectively. The source/drain structure SD52 and the bit line structure RBS51 correspond to two terminals of the switch MS1, respectively. The source/drain structure SDE52 and the bit line structure RBS51 correspond to two terminals of the switch MS52, respectively. The source/drain structure SDE51 and the bit line structure RBS52 correspond to two terminals of the switch MS51, respectively. The source/drain structure SDE53 and the bit line structure RBS52 correspond to two terminals of the switch MS53, respectively.

Furthermore, the word line structure RWS51 is configured to transmit the read word line signal RWL1 to each of the switches MS1 and MS51. The word line structure RWS52 is configured to transmit the read word line signal RWL2 to each of the switches MS52 and MS53. The bit line structure RBS51 is configured to transmit the read bit line signal RBL1 to each of the switches MS1 and MS52. The bit line structure RBS52 is configured to transmit the read bit line signal RBL2 to each of the switches MS51 and MS53.

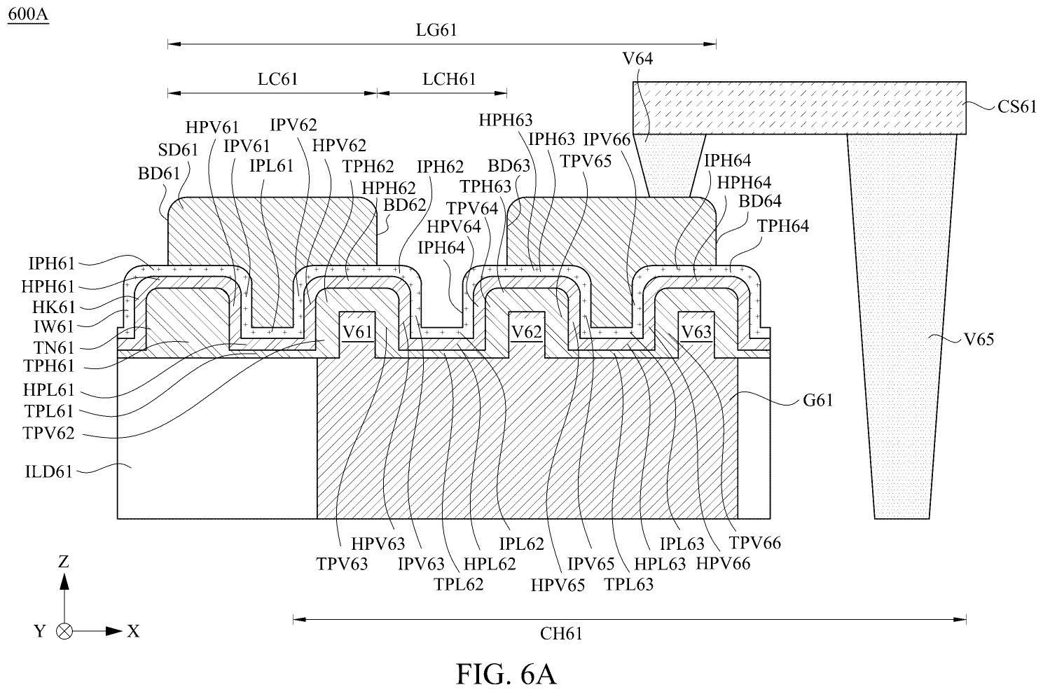

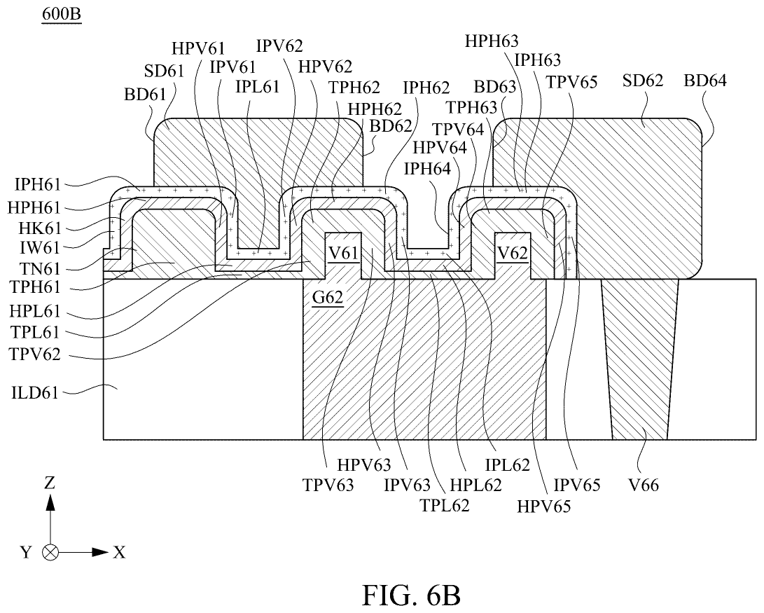

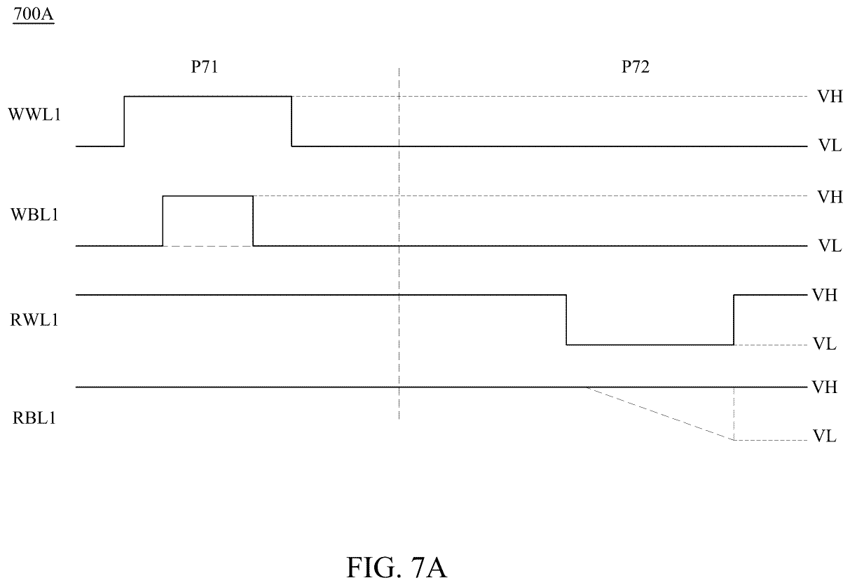

FIG. 6A is a schematic diagram of a cross sectional view of a semiconductor device 600A corresponding to the gain cell 201 shown in FIG. 2A, illustrated in accordance with some embodiments of the present disclosure. The Y direction points into the paper in FIG. 6A.

As illustratively shown in FIG. 6A, the semiconductor device 600A includes a gate structure G61, a channel structure including channel layers IW61, HK61, TN61, source/drain structures SD61, SD62, a conductive segment CS61, an isolation structure ILD61 and via structures V61-V65.

Along the Z direction, each of the via structures V61-V63 is disposed above and coupled to the gate structure G61. The channel layer TN61 is disposed above and coupled to each of the via structures V61-V63. The channel layer HK61 is disposed above and coupled to the channel layer TN61. The channel layer IW61 is disposed above and coupled to the channel layer HK61. Each of the source/drain structures SD61 and SD62 is disposed above and coupled to the channel layer IW61. The via structure V64 is disposed above and coupled to each of the source/drain structure SD62. The conductive segment CS61 is disposed above and coupled to each of the via structures V64 and V65. A part of the via structure is lower than the channel layer TN61 along the Z direction.

The source/drain structure SD61 has boundaries BD61 and BD62 which are opposite to each other along the X direction. The source/drain structure SD62 has boundaries BD63 and BD64 which are opposite to each other along the X direction. The boundaries BD61 and BD62 are separated from each other by a contact length LC61. The boundaries BD63 and BD62 are separated from each other by a channel length LCH61. The boundaries BD61 and BD64 are separated from each other by a gate length LG61. In some embodiments, each of the contact length and the channel length LCH61 is approximately equal to 100 nm.

As illustratively shown in FIG. 6A, the channel layer IW61 includes portions IPH61-IPH64, IPV61-IPV66 and IPL61-IPL63. The channel layer HK61 includes portions HPH61-HPH64, HPV61-HPV66 and HPL61-HPL63. The channel layer TN61 includes portions TPH61-TPH64, TPV62-TPV66 and TPL61-TPL63.

Each of the portions IPH61-IPH64, IPL61-IPL63, HPH61-HPH64, HPL61-HPL63, TPH61-TPH64 and TPL61-TPL63 clongates along the X direction. Each of the portions IPV61-IPV66, HPV61-HPV66 and TPV62-TPV66 clongates along the Y direction. Along the X direction, the portions IPH61, IPL61, IPH62, IPL62, IPH63, IPL64, and IPH64 are arranged in order, the portions HPH61, HPL61, HPH62, HPL62, HPH63, HPL64, and HPH64 are arranged in order, and the portions TPH61, TPL61, TPH62, TPL62, TPH63, TPL64, and TPH64 are arranged in order. The boundaries BD61-BD64 are directly disposed above the portions IPH61-IPH64, respectively.

Along the Z direction, the portions IPH61-IPH64, HPH61-HPH64 and TPH61-TPH64 are higher than the portions IPL61-IPL63, HPL61-HPL63 and TPL61-TPL63. The portion IPV61 contacts to each of the portions IPH61 and IPL61. The portion IPV62 contacts to each of the portions IPH62 and IPL61. The portion IPV63 contacts to each of the portions IPH62 and IPL62. The portion IPV64 contacts to each of the portions IPH63 and IPL62. The portion IPV65 contacts to each of the portions IPH63 and IPL63. The portion IPV66 contacts to each of the portions IPH64 and IPL63.

Similarly, the portion HPV61 contacts to each of the portions HPH61 and HPL61. The portion HPV62 contacts to each of the portions HPH62 and HPL61. The portion HPV63 contacts to each of the portions HPH62 and HPL62. The portion HPV64 contacts to each of the portions HPH63 and HPL62. The portion HPV65 contacts to each of the portions HPH63 and HPL63. The portion HPV66 contacts to each of the portions HPH64 and HPL63.

Similarly, the portion TPV61 contacts to each of the portions TPH61 and TPL61. The portion TPV62 contacts to each of the portions TPH62 and TPL61. The portion TPV63 contacts to each of the portions TPH62 and TPL62. The portion TPV64 contacts to each of the portions TPH63 and TPL62. The portion TPV65 contacts to each of the portions TPH63 and TPL63. The portion TPV66 contacts to each of the portions TPH64 and TPL63. The via structure V61 is interposed between the portions TPV62 and TPV63. The via structure V62 is interposed between the portions TPV64 and TPV65. In some embodiments, along the Z direction, upper boundaries of the via structures V61-V63 are higher than the portions IPL61-IPL63.

With the structural features described above, the channel layers IW61, HK61 and TN61 have a wavy structure. Accordingly, the oxide capacitance of the channel layers IW61, HK61 and TN61 is increased. The gate length effect is increased by 1.5-2 times due to the wavy structure.

Referring to FIG. 2B and FIG. 6A, the gain cell 201 is implemented by the semiconductor device 600A in some embodiments. In such embodiments, the control terminal of the switch MS1 is implemented by the gate structure G61. The two terminals of the switch MS1 are implemented by the source/drain structures SD61 and SD62, respectively. The source/drain structure SD62 is configured to receive the read bit line signal RBL1 through the via structures V64, V65 and the conductive segment CS61. With the wavy structure described above, the capacitance of the storage node N11 is increased, and thus a retention time of the gain cell 201 is increased. The switch MW1 is located below the gate structure GS61 along the Z direction. The gain cell 201 has a cell height CH61 along the X direction. The cell height CH61 is approximately equal to 150 nm.

Referring to FIG. 2A and FIG. 6A, the two source/drain terminals of the switch MS1 are implemented by the source/drain structures SD61 and SD62, respectively. The control terminal of the switch MS1 is implemented by the gate structure GS61.

In some embodiments, the channel layers IW61, HK61 and TN61 have formed with different materials. For example, the channel layer IW61 is formed with indium tungsten oxide (IWO). The channel layer HK61 is formed with high k material, such as hafnium dioxide. The channel layer TN61 is formed with titanium nitride (TiN).

FIG. 6B is a schematic diagram of a cross sectional view of a semiconductor device 600B corresponding to the semiconductor device 600A shown in FIG. 6A, illustrated in accordance with some embodiments of the present disclosure. Referring to FIG. 6B and FIG. 6A, the semiconductor device 600B is an alternative embodiment of the semiconductor device 600A. FIG. 6B follows a similar labeling convention to that of FIG. 6A. For brevity, the discussion will focus more on differences between FIG. 6B and FIG. 6A than on similarities.

Compared to the semiconductor device 600A, the semiconductor device 600B includes a via structure V66 and a gate structure G62 instead of the via structures V63-V65, the conductive segment CS61 and the gate structure G61.

As illustratively shown in FIG. 6B, the via structure V66 extends through the isolation structure ILD61. The source/drain structure SD62 is disposed above and coupled to the via structure V66.

Referring to FIG. 2B and FIG. 6B, the gain cell 201 is implemented by the semiconductor device 600B in some embodiments. In such embodiments, the control terminal of the switch MS1 is implemented by the gate structure G62. The source/drain structure SD62 is configured to receive the read bit line signal RBL1 through the via structures V66. The switch MW1 is located below the gate structure GS62 along the Z direction.

Referring to FIG. 2A and FIG. 6A, the two source/drain terminals of the switch MS1 are implemented by the source/drain structures SD61 and SD62, respectively. The control terminal of the switch MS1 is implemented by the gate structure GS62.

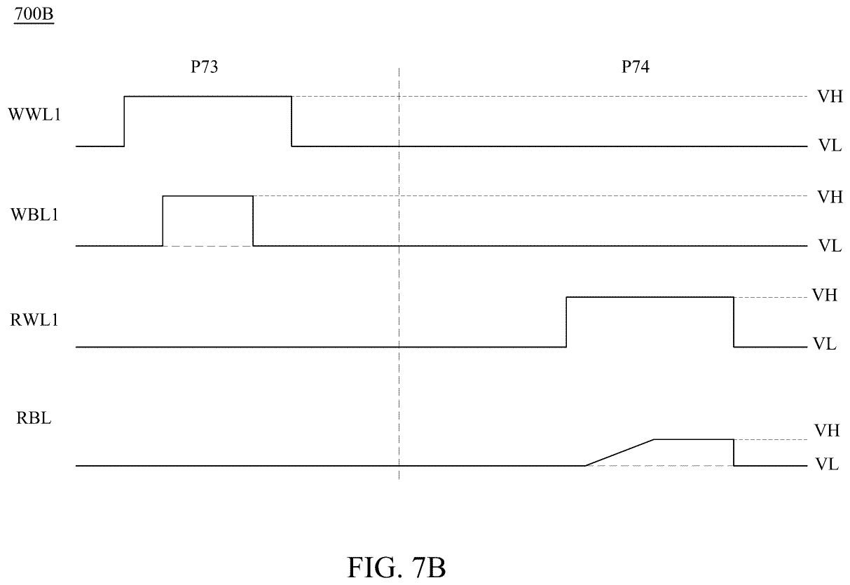

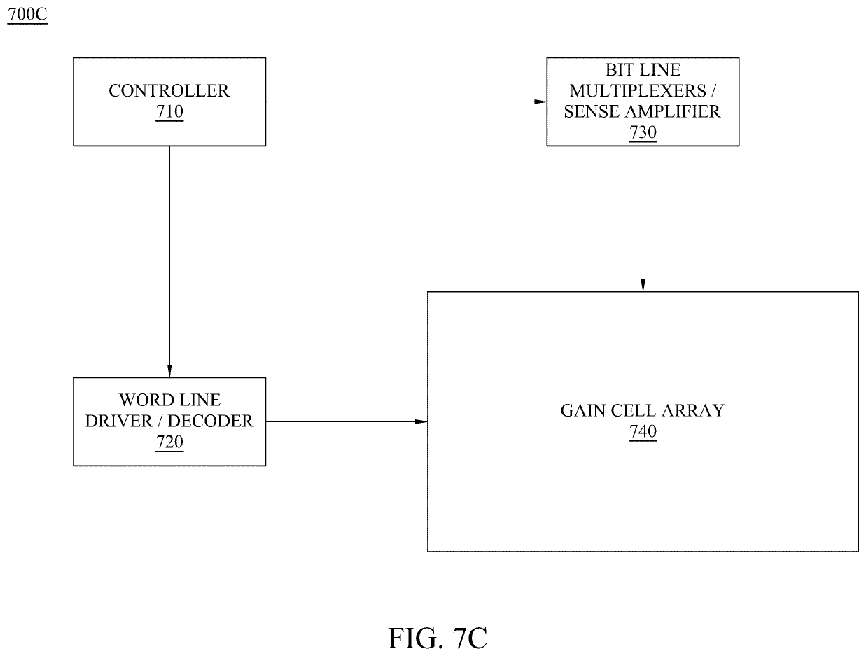

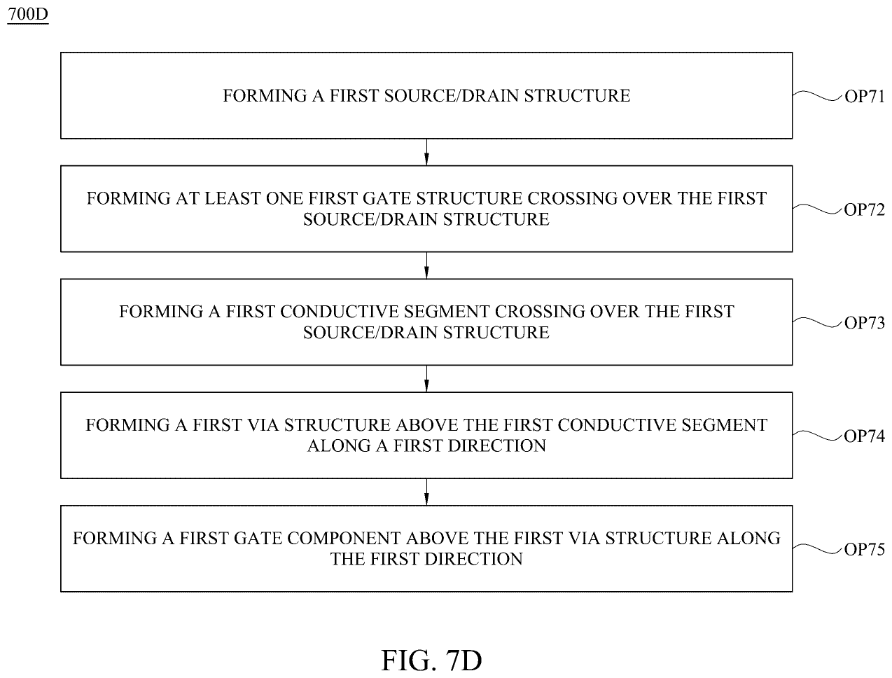

FIG. 7A is a timing diagram 700A of operations of the semiconductor device 100 shown in FIG. 1A, illustrated in accordance with some embodiments of the present disclosure. The timing diagram 700A includes periods P71 and P72 arranged continuously in order. The periods P71 and P72 correspond to a write operation and a read operation, respectively. In the embodiment shown in FIG. 7A, the source line signal SL1 has a power supply voltage level VH. In different embodiments, the source line signal SL1 has a ground voltage level VL.

During the period P71, the write word line signal WWL1 is raised from the voltage level VL to the voltage level VH. In response to writing a logic value 1 into the node N11, the write bit line signal WBL1 is raised from the voltage level VL to the voltage level VH. In response to writing a logic value 0 into the node N11, the write bit line signal WBL1 is maintained at the voltage level VL. Each of the read word line signal RWL1 and the read bit line signal RBL1 is maintained at the voltage level VH.

During the period P72, the read word line signal RWL1 is fallen from the voltage level VH to the voltage level VL. In response to reading the logic value 1 from the node N11, the read bit line signal RBL1 is maintained at the voltage level VH. In response to reading the logic value 0 from the node N11, the read bit line signal RBL1 is fallen from the voltage level VH to the voltage level VL. Each of the write word line signal WWL1 and the write bit line signal WBL1 is maintained at the voltage level VL. In some embodiments, a sense amplifier (not shown in figures) is configured to sense the read bit line signal RBL1.

FIG. 7B is a timing diagram 700B of operations of the semiconductor device 200 shown in FIG. 2A, illustrated in accordance with some embodiments of the present disclosure. The timing diagram 700B includes periods P73 and P74 arranged continuously in order. The periods P73 and P74 correspond to a write operation and a read operation, respectively.

During the period P73, the write word line signal WWL1 is raised from the voltage level VL to the voltage level VH. In response to writing the logic value 1 into the node N11, the write bit line signal WBL1 is raised from the voltage level VL to the voltage level VH. In response to writing the logic value 0 into the node N11, the write bit line signal WBL1 is maintained at the voltage level VL. Each of the read word line signal RWL1 and the read bit line signal RBL1 is maintained at the voltage level VL.

During the period P74, the read word line signal RWL1 is raised from the voltage level VL to the voltage level VH. In response to reading the logic value 0 from the node N11, the read bit line signal RBL1 is maintained at the voltage level VL. In response to reading the logic value 1 from the node N11, the read bit line signal RBL1 is raised from the voltage level VL to the voltage level VH. Each of the write word line signal WWL1 and the write bit line signal WBL1 is maintained at the voltage level VL. In some embodiments, a sense amplifier (not shown in figures) is configured to sense the read bit line signal RBL1. In various embodiments, the sense amplifier is implemented by a voltage sense amplifier or a current sense amplifier.

FIG. 7C is a schematic diagram of a memory system 700C, illustrated in accordance with some embodiments of the present disclosure. The memory system 700C includes a controller 710, a word line device 720, a bit line device 730 and a memory device 740.

In some embodiments, the word line device 720 is implemented by a word line driver and a word line decoder. The bit line device 730 is implemented by bit line multiplexers and a sense amplifier. The memory device 740 is implemented by a gain cell array, which includes multiple gain cells, such as the gain cells 101, 201, 401-403 and 501-503 described above.

In some embodiments, the controller 710 is configured to control the word line device 720 and the bit line device 730. The word line device 720 is configured generate write word line signals WWL and read word line signals RWL to the memory device 740. The bit line device 730 is configured generate and receive write bit line signals WBL and read bit line signals RBL from and to the memory device 740.

In some embodiments, the write word line signals WWL includes the write word line signals WWL1 and WWL2 described above. The read word line signals RWL includes the read word line signals RWL1 and RWL2 described above. The write bit line signals WBL includes the write bit line signals WBL1 and WBL2 described above. The read bit line signals RBL includes the read bit line signals RBL1 and RBL2 described above.

FIG. 7D is a flowchart diagram of a method 700D for fabricating the memory devices described above, illustrated in accordance with some embodiments of the present disclosure. The method 700D includes operations OP71-OP75.

During the operation OP71, a first source/drain structure is formed. For example, the source/drain structure SD31 shown in FIG. 4A or the source/drain structure SD51 shown in FIG. 5A is formed.

During the operation OP72, at least one first gate structure crossing over the first source/drain structure is formed. For example, the gate structures GS31, GS32 shown in FIG. 4A or the gate structures GS51, GS52 shown in FIG. 5A are formed.

During the operation OP73, a first conductive segment crossing over the first source/drain structure is formed. For example, the conductive segment CS32 shown in FIG. 4A or the conductive segment CS52 shown in FIG. 5A is formed.

During the operation OP74, a first via structure above the first conductive segment along a first direction is formed. For example, the via structure VM42 above the conductive segment CS32 along the Z direction shown in FIG. 4A or the via structure VM52 above the conductive segment CS52 along the Z direction shown in FIG. 5A is formed.

During the operation OP75, a first gate component above the first via structure along the first direction is formed. For example, the gate component GC41 above the via structure VM42 along the Z direction shown in FIG. 4B or the gate component GC51 above the via structure VM52 along the Z direction shown in FIG. 5A are formed.

In some embodiments, the first via structure couples the first conductive segment to the first gate component, and the first gate component corresponds to a first storage node of a first gain cell. For example, the gate component GC41 corresponds to the storage node N11 of the gain cell 101, and the gate component GC51 corresponds to the storage node N11 of the gain cell 201.

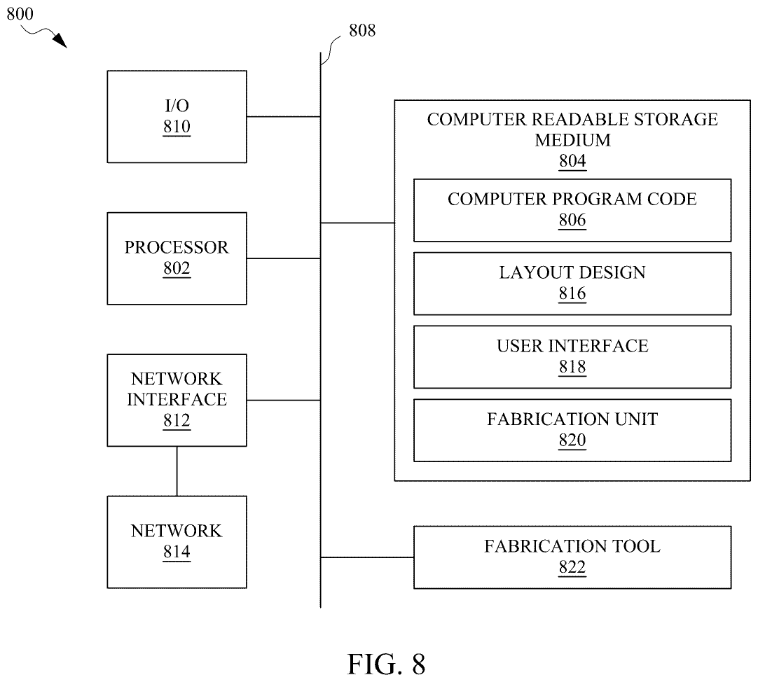

FIG. 8 is a schematic view of a system 800 for designing and manufacturing at least one of the semiconductor devices described above, illustrated in accordance with some embodiments of the present disclosure. The system 800 generates or places one or more IC layout designs corresponding to at least one of the semiconductor devices described above, as described herein. In some embodiments, the system 800 manufactures one or more semiconductor devices based on the one or more IC layout designs, as described herein. The system 800 includes a hardware processor 802 and a non-transitory, computer readable storage medium 804 encoded with, e.g., storing, the computer program code 806, e.g., a set of executable instructions. The computer readable storage medium 804 is configured for interfacing with manufacturing machines for producing the semiconductor device. The processor 802 is electrically coupled to the computer readable storage medium 804 by a bus 808. The processor 802 is also electrically coupled to an I/O interface 810 by the bus 808. A network interface 812 is also electrically connected to the processor 802 by the bus 808. Network interface 812 is connected to a network 814, so that the processor 802 and the computer readable storage medium 804 are capable of connecting to external elements via network 814. The processor 802 is configured to execute the computer program code 806 encoded in the computer readable storage medium 804 in order to cause the system 800 designing and manufacturing at least one of the semiconductor devices described above.

In some embodiments, the processor 802 is a central processing unit (CPU), a multi-processor, a distributed processing system, an application specific integrated circuit (ASIC), and/or a suitable processing unit.

In some embodiments, the computer readable storage medium 804 is an electronic, magnetic, optical, electromagnetic, infrared, and/or a semiconductor system (or apparatus or device). For example, the computer readable storage medium 804 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 804 includes a compact disk-read only memory (CD-ROM), a compact disk-read/write (CD-R/W), and/or a digital video disc (DVD).

In some embodiments, the storage medium 804 also stores information needed for designing and manufacturing at least one of the semiconductor devices described above, such as layout design 816, user interface 818, fabrication unit 820, and/or a set of executable instructions to designing and manufacturing at least one of the semiconductor devices described above.

In some embodiments, the storage medium 804 stores instructions (e.g., the computer program code 806) for interfacing with manufacturing machines. The instructions (e.g., the computer program code 806) enable the processor 802 to generate manufacturing instructions readable by the manufacturing machines to effectively implement the semiconductor devices described above.

The system 800 includes the I/O interface 810. The I/O interface 810 is coupled to external circuitry. In some embodiments, the I/O interface 810 includes a keyboard, keypad, mouse, trackball, trackpad, and/or cursor direction keys for communicating information and commands to the processor 802.

The system 800 also includes the network interface 812 coupled to the processor 802. The network interface 812 allows the system 800 to communicate with the network 814, to which one or more other computer systems are connected. The network interface 812 includes wireless network interfaces such as BLUETOOTH, WIFI, WIMAX, GPRS, or WCDMA; or wired network interface such as ETHERNET, USB, or IEEE-13154. In some embodiments, the designing and manufacturing of at least one of the semiconductor devices described above is implemented in two or more systems 800, and information such as layout design, user interface and fabrication unit are exchanged between different systems 800 by the network 814.

The system 800 is configured to receive information related to a layout design through the I/O interface 810 or network interface 812. The information is transferred to the processor 802 by the bus 808 to determine a layout design for producing an IC. The layout design is then stored in the computer readable medium 804 as the layout design 816. The system 800 is configured to receive information related to a user interface through the I/O interface 810 or network interface 812. The information is stored in the computer readable medium 804 as the user interface 818. The system 800 is configured to receive information related to a fabrication unit through the I/O interface 810 or network interface 812. The information is stored in the computer readable medium 804 as the fabrication unit 820. In some embodiments, the fabrication unit 820 includes fabrication information utilized by the system 800.

In some embodiments, the designing and manufacturing of at least one of the semiconductor devices described above is implemented as a standalone software application for execution by a processor. In some embodiments, the designing and manufacturing of at least one of the semiconductor devices described above is implemented as a software application that is a part of an additional software application. In some embodiments, the designing and manufacturing of at least one of the semiconductor devices described above is implemented as a plug-in to a software application. In some embodiments, the designing and manufacturing of at least one of the semiconductor devices described above is implemented as a software application that is a portion of an EDA tool. In some embodiments, the designing and manufacturing of at least one of the semiconductor devices described above is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, at least one of the semiconductor devices described above is implemented by a manufacturing device to manufacture an integrated circuit using a set of masks manufactured based on one or more layout designs generated by the system 800. In some embodiments, the system 800 includes a manufacturing device (e.g., fabrication tool 822) to manufacture an integrated circuit using a set of masks manufactured based on one or more layout designs of the present disclosure.

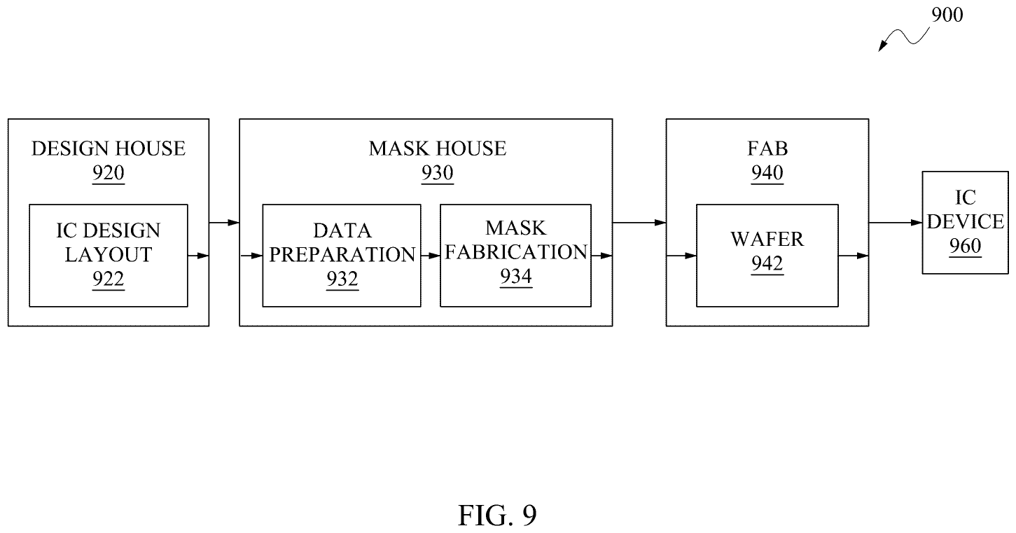

FIG. 9 is a block diagram of an integrated circuit (IC)/semiconductor device manufacturing system 900, and an IC manufacturing flow associated therewith, illustrated in accordance with some embodiments of the present disclosure.

In FIG. 9, the IC manufacturing system 900 includes entities, such as a design house 920, a mask house 930, and an IC manufacturer/fabricator (“fab”) 940, that interact with one another in the design, development, and manufacturing cycles and/or services related to manufacturing an IC device (semiconductor device) 960 including at least one of the semiconductor devices described above. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 920, mask house 930, and IC fab 940 is owned by a single company. In some embodiments, two or more of design house 920, mask house 930, and IC fab 940 coexist in a common facility and use common resources.

The design house (or design team) 920 generates an IC design layout 922. The IC design layout 922 includes various geometrical patterns designed for the IC device 960. The geometrical patterns correspond to patterns of metal, oxide, or semiconductor layers that make up the various components of the IC device 960 to be fabricated. The various layers combine to form various IC features. For example, a portion of the IC design layout 922 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 920 implements a proper design procedure to form the IC design layout 922. The design procedure includes one or more of logic design, physical design or place and route. The IC design layout 922 is presented in one or more data files having information of the geometrical patterns. For example, the IC design layout 922 can be expressed in a GDSII file format or DFII file format.

The mask house 930 includes mask data preparation 932 and mask fabrication 934. The mask house 930 uses the IC design layout 922 to manufacture one or more masks to be used for fabricating the various layers of the IC device 960 according to the IC design layout 922. The mask house 930 performs the mask data preparation 932, where the IC design layout 922 is translated into a representative data file (“RDF”). The mask data preparation 932 provides the RDF to the mask fabrication 934. The mask fabrication 934 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 932 to comply with particular characteristics of the mask writer and/or requirements of the IC fab 940. In FIG. 9, the mask data preparation 932 and mask fabrication 934 are illustrated as separate elements. In some embodiments, the mask data preparation 932 and mask fabrication 934 can be collectively referred to as mask data preparation.

In some embodiments, the mask data preparation 932 includes optical proximity correction (OPC) which uses lithography enhancement techniques to compensate for image errors, such as those that can arise from diffraction, interference, other process effects and the like. OPC adjusts the IC design layout 922. In some embodiments, the mask data preparation 932 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 934, which may undo part of the modifications performed by OPC in order to meet mask creation rules.

In some embodiments, the mask data preparation 932 includes lithography process checking (LPC) that simulates processing that will be implemented by the IC fab 940 to fabricate the IC device 960. LPC simulates this processing based on the IC design layout 922 to create a simulated manufactured device, such as the IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 922.

It should be understood that the above description of the mask data preparation 932 has been simplified for the purposes of clarity. In some embodiments, the mask data preparation 932 includes additional features such as a logic operation (LOP) to modify the IC design layout according to manufacturing rules. Additionally, the processes applied to the IC design layout 922 during the mask data preparation 932 may be executed in a variety of different orders.

After the mask data preparation 932 and during mask fabrication 934, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 940 is an IC fabrication entity that includes one or more manufacturing facilities for the fabrication of a variety of different IC products. In some embodiments, the IC fab 940 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 940 uses the mask (or masks) fabricated by the mask house 930 to fabricate the IC device 960. Thus, the IC fab 940 at least indirectly uses the IC design layout 922 to fabricate the IC device 960. In some embodiments, a semiconductor wafer is fabricated by the IC fab 940 using the mask (or masks) to form the IC device 960. The semiconductor wafer 942 includes a silicon substrate or other proper substrate having material layers formed thereon. Semiconductor wafer further includes one or more of various doped regions, dielectric features, multilevel interconnects, and the like (formed at subsequent manufacturing steps).

Also disclosed is a device. The device includes a first gain cell. The first gain cell includes a first switch and a second switch. The switch is configured to transmit a first bit line signal to a first storage node. The second switch at least includes a first gate structure coupled to the first storage node and a first source/drain structure corresponding to a first terminal of the second switch. Along a first direction, the first gate structure is disposed above the first switch and the first source/drain structure is disposed above the first gate structure.

Also disclosed is a method. The method includes: forming a first source/drain structure; forming at least one first gate structure crossing over the first source/drain structure; forming a first conductive segment crossing over the first source/drain structure; forming a first via structure above the first conductive segment along a first direction; and forming a first gate component above the first via structure along the first direction. The first via structure couples the first conductive segment to the first gate component, and the first gate component corresponds to a first storage node of a first gain cell.

Also disclosed is a device. The device includes a first source/drain structure, at least one first gate structure, a first conductive segment and a first gate component. The at least one first gate structure crosses over the first source/drain structure. The first conductive segment crosses over the first source/drain structure. The first gate component is disposed above and coupled to the first conductive segment, and corresponding to a first storage node of a first gain cell. Along a first direction, the first conductive segment is disposed between the first source/drain structure and the first gate component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising a first gain cell, the first gain cell comprising:
a first switch configured to transmit a first bit line signal to a first storage node; and
a second switch at least comprising a first gate structure coupled to the first storage node and a first source/drain structure corresponding to a first terminal of the second switch,
wherein along a first direction, the first gate structure is disposed above the first switch and the first source/drain structure is disposed above the first gate structure.

2. The device of claim 1, wherein the second switch further comprises:
a second source/drain structure corresponding to a second terminal of the second switch and disposed above the first gate structure along the first direction.

3. The device of claim 2, further comprising:
a third switch coupled to the second source/drain structure,
wherein the second source/drain structure is disposed above the third switch along the first direction.

4. The device of claim 1, further comprising:
a first word line structure configured to transmit a word line signal to the first switch and disposed above the first switch along the first direction,
wherein the first gate structure is disposed above and overlapped with the first word line structure along the first direction.

5. The device of claim 1, further comprising:
a third switch configured to transmit the first bit line signal to a second storage node; and
a fourth switch at least comprising a second gate structure coupled to the second storage node,
wherein the first source/drain structure is coupled to and overlapped with each of the first gate structure and the second gate structure along the first direction.

6. The device of claim 5, further comprising:
a fifth switch configured to transmit a second bit line signal to a third storage node;
a sixth switch at least comprising a third gate structure coupled to the third storage node; and
a word line structure coupled to each of control terminals of the first switch and the fifth switch, and disposed above the first switch and the fifth switch along the first direction,
wherein each of the first gate structure and the third gate structure is disposed above and overlapped with the word line structure along the first direction.

7. The device of claim 1, further comprising:
a second source/drain structure coupled to and disposed above first gate structure along the first direction, and separated from the first source/drain structure along a second direction different from the first direction; and
a word line structure crossing over each of the first source/drain structure and the second source/drain structure, and coupled to the second source/drain structure.

8. The device of claim 7, further comprising:
a second gate structure coupled to a second storage node,
wherein the first source/drain structure is disposed above the second gate structure along the first direction and is coupled to the second gate structure.

9. The device of claim 7, further comprising:
a second gate structure coupled to a second storage node; and
a third source/drain structure disposed above the second gate structure along the first direction and is coupled to the second gate structure,
wherein the word line structure crosses over and coupled to the third source/drain structure.

10. The device of claim 1, wherein the second switch further comprises:
a second source/drain structure separated from the first source/drain structure along a second direction different from the first direction; and
a channel structure disposed between the first gate structure and the first source/drain structure along the first direction,
wherein the channel structure comprises a first portion, a second portion and a third portion arranged along the second direction in order,
each of the first portion, the second portion and the third portion is elongated along the second direction, and
the second portion is lower than each of the first portion and the third portion along the first direction.

11. A method, comprising:
forming a first source/drain structure;
forming at least one first gate structure crossing over the first source/drain structure;
forming a first conductive segment crossing over the first source/drain structure;
forming a first via structure above the first conductive segment along a first direction; and
forming a first gate component above the first via structure along the first direction,
wherein the first via structure couples the first conductive segment to the first gate component, and
the first gate component corresponds to a first storage node of a first gain cell.

12. The method of claim 11, further comprising:
forming a first source line structure and a first source/drain structure each overlapped with the first gate component along the first direction,
wherein the first source line structure and the first source/drain structure correspond to two terminal of a first switch in the first gain cell, respectively.

13. The method of claim 12, further comprising:
forming a second gate component corresponding to a second storage node of a second gain cell,
wherein the first source line structure is further overlapped with the second gate component along the first direction, and
the source line structure corresponds to a terminal of a second switch in the second gain cell.

14. The method of claim 12, further comprising:
forming a second gate component corresponding to a second storage node of a second gain cell; and
forming a second source line structure and a second source/drain structure each overlapped with the second gate component along the first direction,
wherein the second source line structure and the second source/drain structure correspond to two terminal of a second switch in the second gain cell, respectively.

15. The method of claim 11, further comprising:
forming a first bit line structure and a first source/drain structure each overlapped with the first gate component along the first direction; and
forming a first word line structure crossing over each of the first bit line structure and the first source/drain structure, and coupled to the first source/drain structure,
wherein the first bit line structure and the first source/drain structure correspond to two terminal of a first switch in the first gain cell, respectively.

16. The method of claim 15, further comprising:
forming a second gate component corresponding to a second storage node of a second gain cell; and
forming a second bit line structure and a second source/drain structure each overlapped with the second gate component along the first direction,
wherein the first word line structure further crosses over each of the second bit line structure and the second source/drain structure, and
the second bit line structure and the second source/drain structure correspond to two terminal of a second switch in the first gain cell, respectively.

17. The method of claim 15, further comprising:
forming a second gate component corresponding to a second storage node of a second gain cell; and
forming a second source/drain structure overlapped with the second gate component along the first direction; and
forming a second word line structure crossing over each of the first bit line structure and the second source/drain structure, and coupled to the second source/drain structure,
wherein the first bit line structure and the second source/drain structure correspond to two terminal of a first switch in the second gain cell, respectively.

18. A device, comprising:
a first source/drain structure;
at least one first gate structure crossing over the first source/drain structure;
a first conductive segment crossing over the first source/drain structure; and
a first gate component disposed above and coupled to the first conductive segment, and corresponding to a first storage node of a first gain cell,
wherein along a first direction, the first conductive segment is disposed between the first source/drain structure and the first gate component, and
the first conductive segment is disposed between two of the at least one first gate structure along a second direction different from the first direction.

19. The device of claim 18, further comprising:
a source line structure overlapped with the first gate component along the first direction; and
a second source/drain structure overlapped with the first gate component along the first direction,
wherein the source line structure and the second source/drain structure are separated from each other along a third direction different from each of the first direction and the second direction, and
the source line structure and the second source/drain structure correspond to two terminal of a first switch in the first gain cell, respectively.

20. The device of claim 18, further comprising:
a bit line structure overlapped with the first gate component along the first direction;
a second source/drain structure overlapped with the first gate component along the first direction; and
a word line structure crossing over each of the bit line structure and the second source/drain structure, and coupled to the second source/drain structure,
wherein the bit line structure and the second source/drain structure correspond to two terminal of a first switch in the first gain cell, respectively.
